(19) United States
(12) Patent Application Publication
(10) Pub. No.: US 2006/0222902 A1
(43) Pub. Date: Oct. 5, 2006

(54) Perpendicular magnetic recording medium, manufacturing method thereof, and magnetic storage device

(75) Inventor: Ryoichi Mukai, Kawasaki (JP)

Correspondence Address: Patrick G. Burns, Esq.;Greer, Burns & Crain, Ltd., Suite 2500, 300 S. Wacker Drive, Chicago, IL, 60606, US

(73) Assignee: FUJITSU LIMITED

(21) Appl. No.: 11/388,547

(22) Filed: Mar. 24, 2006

Related U.S. Application Data
(63) Continuation-in-part of application No. 11/158,623, filed on Jun. 22, 2005, now abandoned.

(30) Foreign Application Priority Data
Mar. 30, 2005 (JP) 2005-099885
Feb. 24, 2006 (JP) 2006-049313

(51) Int. Cl. G11B 5/66; C23C 14/00

(52) U.S. Cl. 428/827; 428/831.2; 428/836.3; 204/192.2

(57) ABSTRACT

A perpendicular magnetic recording medium for enabling high density recording is disclosed. The perpendicular magnetic recording medium includes a substrate on which a soft magnetic underlayer, a seed layer made of a non-crystalline material, an underlayer made of Ru or an Ru alloy including Ru as a main component, and a recording layer including a first magnetic layer and a second magnetic layer. The first and second magnetic layers include a plurality of magnetic grains having easy magnetization axes in a substantially perpendicular direction with respect to the substrate surface, and first and second nonmagnetic non-soluble phases segregating the magnetic grains of the first and second magnetic layers, respectively. The first magnetic layer includes the first non-soluble phase at a first atomic concentration that is higher than a second atomic concentration of the second non-soluble phase in the second magnetic layer.

### CROSS-REFERNCE TO RELATED APPLICATION

This application is a U.S. continuation-in-part application filed under 35 USC 111(a) and claiming benefit under 35 USC 120 of U.S. patent application Ser. No. 11/158,623, filed on Jun. 22, 2005.

### BACKGROUND OF THE INVENTION

1. Field of the Invention

The present invention generally relates to a perpendicular magnetic recording medium, a manufacturing method thereof, and a magnetic storage device. The present invention particularly relates to a perpendicular magnetic recording medium including a recording layer in which magnetic grains are segregated by a non-magnetic material.

2. Description of the Related Art

A magnetic storage device such as a hard disk drive corresponds to a digital signal storage device with a low memory unit cost (per bit) that is suitable for realizing capacity increase. In recent years and continuing, with the development of applications of the hard disk drive to personal computers and digital image/audio equipment, for example, the demand for the hard disk drive is on the rise. Also, a further capacity increase of the hard disk drive is demanded.

Storage capacity increase and cost reduction of the hard disk drive may be realized at the same time by realizing higher density recording on a magnetic recording medium. By realizing higher density recording, the number of magnetic recording media may be reduced, and in turn, the number of magnetic heads may be reduced so that cost reduction may be realized.

In one example, higher density recording in the magnetic recording medium may be realized by improving the S/N ratio through increasing the resolution and decreasing noise. It is noted that noise decrease is conventionally realized by decreasing the grain size of magnetic grains provided in a recording layer and magnetically segregating the magnetic grains.

A perpendicular magnetic recording medium includes a substrate on which a soft magnetic underlayer made of soft magnetic material and a recording layer are laminated in this order. The recording layer is normally made of CoCr alloy and is formed through sputtering. In this case, the substrate is heated while sputtering of the CoCr alloy is conducted. In this way, magnetic grains made of CoCr alloy that are rich in Co may be formed, and Cr that is nonmagnetic may be concentrated at the grain boundaries of the magnetic grains so that magnetic segregation of the magnetic grains may be realized.

The soft magnetic underlayer forms a magnetic path for magnetic flux that flows through a magnetic head during recording or reproducing. When the soft magnetic underlayer is made of crystalline material, spike noise may be generated due to the formation of a magnetic domain. Therefore, the soft magnetic underlayer is preferably made of non-crystalline or microcrystalline material so that a magnetic domain may not be easily formed. It is noted that the heating temperature for heating the substrate upon forming the recording layer is restricted in order to prevent crystallization of the soft magnetic underlayer.

In this regard, a recording layer has been proposed in the prior art in which magnetic grains made of CoCr alloy are segregated from each other by a nonmagnetic parent phase made of SiO₂, such a recording layer realizing improved magnetic segregation without requiring high temperature thermal processing. The structure of such a recording medium is referred to as a granular structure (e.g., see Japanese Laid-Open Patent Publication No. 2003-217107 and Japanese Laid-Open Patent Publication No. 2003-346334).

In a case where a recording layer has a granular structure, if the recording layer is simply formed on a seed layer, the magnetic grains may bond with each other and grow, or the space between the magnetic grains (magnetic spacing) may be uneven. When the magnetic grains bond with one another, the grain size (diameter) distribution range of the magnetic grains may increase. Also, when the space between the magnetic grains becomes uneven, interaction between the magnetic grains may not be sufficiently decreased. As a result, the medium noise of the recording layer may increase, and degradation of the S/N ratio may occur.

### SUMMARY OF THE INVENTION

The present invention has been conceived in response to one or more of the problems of the related art, and its object is to provide a perpendicular magnetic recording medium realizing low medium noise and a good S/N ratio and being capable of high density recording. The present invention also relates to a manufacturing method of such a recording medium and a magnetic storage device.

It is another object of the present invention to provide a perpendicular magnetic recording medium that is capable of realizing a good S/N ratio and a high output in playback, a method for manufacturing such a perpendicular magnetic recording medium, and a magnetic storage device.

According to an aspect of the present invention, a perpendicular magnetic recording medium is provided that includes:

a substrate;

a soft magnetic underlayer that is formed on the substrate;

a seed layer made of a non-crystalline material that is formed on the soft magnetic underlayer;

a first underlayer made of Ru or an Ru alloy including Ru as a main component that is formed on the seed layer; and

a recording layer including a first magnetic layer and a second magnetic layer that is formed on the first underlayer; wherein

the first underlayer includes a polycrystalline film that is formed by a plurality of first crystal grains that are bonded to each other via a crystal boundary portion;

the first magnetic layer includes a plurality of first magnetic grains having easy magnetization axes in a substantially perpendicular direction with respect to the substrate surface, and a first nonmagnetic non-soluble phase segregating the first magnetic grains from each other, which first non-soluble phase is provided at a first atomic concentration;

the second magnetic layer includes a plurality of second magnetic grains having easy magnetization axes in a substantially perpendicular direction with respect to the substrate surface, and a second nonmagnetic non-soluble phase segregating the second magnetic grains from each other, which second non-soluble phase is provided at a second atomic concentration; and

the first atomic concentration of the first non-soluble phase in the first magnetic layer is arranged to be higher than the second atomic concentration of the second non-soluble phase in the second magnetic layer.

According to an embodiment of the present invention, since the crystal grains of the underlayer are formed on the seed layer made of non-crystalline material, the grain diameters of the crystal grains may be uniform, and the crystal grains of the underlayer may be evenly formed. Since the magnetic grains of the first magnetic layer are grown on the surfaces of the crystal grains of the underlayer, and the second magnetic layer are grown on the surfaces of the magnetic grains of the first magnetic layer, the magnetic grains of the first and second magnetic layers may be evenly formed as well. Also, since the underlayer is made of Ru or a Ru alloy including Ru as a main component, good lattice compatibility may be realized with the magnetic grains of the first magnetic layer. Further, since the first magnetic layer is arranged to include the first non-soluble phase at an atomic concentration that is higher than that in the second magnetic layer, the magnetic grains of the first magnetic layer may be sufficiently segregated upon being grown. That is, in the first magnetic layer, bonding of the magnetic grains may be prevented by the non-soluble phase. The magnetic grains of the second magnetic layer are grown on the surfaces of the magnetic grains of the first magnetic layer on a one-to-one basis, and thereby, the magnetic grains of the second magnetic layer may also be sufficiently segregated. In this way, the magnetic grains of the first magnetic layer and the second magnetic layer may be evenly formed and realize good crystalline structure, and the magnetic grains may be sufficiently segregated from one another so that the medium noise may be reduced. As a result, the S/N ratio may be improved and high density recording may be realized in the perpendicular magnetic recording medium.

According to another aspect of the present invention, a perpendicular magnetic recording medium is provided that includes:

a substrate;

a soft magnetic underlayer that is formed on the substrate;

a seed layer made of a non-crystalline material, which seed layer is formed on the soft magnetic underlayer;

a first underlayer made of Ru or an Ru alloy including Ru as a main component, which first underlayer is formed on the seed layer; and

a recording layer including a first magnetic layer and a second magnetic layer that is laminated on the first magnetic layer, which recording layer is formed on the first underlayer; wherein

the first underlayer includes a polycrystalline film that is formed by a plurality of first crystal grains that are bonded to each other via a crystal boundary portion;

the first magnetic layer includes a plurality of first magnetic grains having easy magnetization axes in a substantially perpendicular direction with respect to the substrate surface, and a nonmagnetic non-soluble phase segregating the first magnetic grains from each other, which first magnetic layer is arranged to have a first saturation flux density;

the second magnetic layer is made of a metallic hard magnetic material and includes a plurality of second magnetic grains having easy magnetization axes in a substantially perpendicular direction with respect to the substrate surface, which second magnetic layer is arranged to have a second saturation flux density;

the second saturation flux density of the second magnetic layer is arranged to be higher than the first saturation flux density of the first magnetic layer; and

the second magnetic grains of the second magnetic layer are arranged on surfaces of the first magnetic grains of the first magnetic layer.

According to an embodiment of the present invention, a perpendicular magnetic recording medium includes a recording medium that is realized by depositing a second magnetic layer made of a metallic hard magnetic material on a first magnetic layer having a granular structure. Since the magnetic grains of the first magnetic layer are arranged into a granular structure, the magnetic grains of the first magnetic layer may be evenly arranged. In turn, since the magnetic grains of the second magnetic layer are formed on the magnetic grains of the first magnetic layer, the even arrangement of the magnetic grains of the first magnetic layer may be passed on to the second magnetic layer. In this way, the magnetic grains of the second magnetic layer may also be evenly arranged. As a result, medium noise of the perpendicular magnetic recording medium may be reduced. Also, since the saturation flux density of the second magnetic layer is arranged to be higher than the saturation flux density of the first magnetic layer, the overall film thickness of the recording layer may be reduced, and since the saturation flux density is higher at the layer that is closer to the magnetic head, the playback output level of the perpendicular magnetic recording medium may be increased to a higher output level. In this way, a good S/S ratio and high playback output may both be achieved in the perpendicular magnetic recording medium.

According to another aspect of the present invention, a magnetic storage device is provided that includes a recording/reproducing unit with a magnetic head, and a perpendicular magnetic recording medium according to an embodiment of the present invention. Since medium noise is reduced and in the perpendicular magnetic recording medium according to an embodiment of the present invention, the S/N ratio may be improved and high density recording may be enabled.

According to another aspect of the present invention, a method of manufacturing a perpendicular magnetic recording medium that includes a substrate on which a soft magnetic underlayer, a seed layer, a first underlayer, a first magnetic layer, and a second magnetic layer are consecutively formed, which first and second magnetic layers respectively include a plurality of magnetic grains having easy magnetization axes in a direction substantially perpendicular to the substrate surface and nonmagnetic non-soluble phases segregating the magnetic grains, the method including the steps of:

forming the seed layer made of a non-crystalline material on the soft magnetic underlayer;

forming the first underlayer made of Ru or an Ru alloy including Ru as main component on the seed layer;

forming the first magnetic layer on the first underlayer through sputtering using a first sputtering target; and

forming the second magnetic layer on the first magnetic layer through sputtering using a second sputtering target; wherein

the first sputtering target and the second sputtering target include a hard magnetic material and a nonmagnetic material that is made of any one of an oxide, a carbide, or a nitride; and

the first sputtering target includes the nonmagnetic material at an atomic concentration that is higher than an atomic concentration of the nonmagnetic material in the second sputtering target.

According to an embodiment of the present invention, the crystal grains are evenly formed in the underlayer, and the first magnetic layer with a high atomic concentration of nonmagnetic material is formed on the underlayer, after which the second magnetic layer with a lower concentration of the nonmagnetic material is formed on the first magnetic layer. In this way, the magnetic grains of the first and second magnetic layers may be evenly formed, and bonding of the magnetic grains may be prevented so that a perpendicular magnetic recording medium with reduced medium noise may be realized. In turn, a perpendicular magnetic recording medium with an improved S/N ratio that is capable of high density recording may be realized.

### BRIEF DESCRIPTION OF THE DRAWINGS

FIG. 1 is a cross-sectional diagram showing a configuration of a perpendicular magnetic recording medium according to a first embodiment of the present invention;

FIG. 2 is a diagram showing a detailed structure of the perpendicular magnetic recording medium shown in FIG. 1;

FIG. 3 is a cross-sectional view of FIG. 2 cut across line A-A;

FIG. 4 is a cross-sectional diagram showing a configuration of a perpendicular magnetic recording medium according to a second embodiment of the present invention;

FIG. 5 is a diagram showing a detailed structure of the perpendicular magnetic recording medium shown in FIG. 4;

FIG. 6 is a cross-sectional diagram showing a configuration of a perpendicular magnetic recording medium according to a third embodiment of the present invention;

FIG. 7 is a cross-sectional diagram showing a configuration of a perpendicular magnetic recording medium according to a fourth embodiment of the present invention;

FIG. 8 is a cross-sectional diagram showing a configuration of a perpendicular magnetic recording medium according to a fifth embodiment of the present invention;

FIG. 9 is a cross-sectional diagram showing a configuration of a perpendicular magnetic recording medium according to a sixth embodiment of the present invention;

FIG. 10 is a cross-sectional diagram showing a configuration of a perpendicular magnetic recording medium according to a seventh embodiment of the present invention;

FIG. 11 is a diagram showing a detailed structure of the perpendicular magnetic recording medium shown in FIG. 10;

FIG. 12 is a cross-sectional view of FIG. 11 cut across line B-B;

FIG. 13 is a cross-sectional diagram showing a configuration of a perpendicular magnetic recording medium according to an eighth embodiment of the present invention;

FIG. 14 is a diagram showing a detailed structure of the perpendicular magnetic recording medium shown in FIG. 13;

FIG. 15 is a cross-sectional diagram showing a configuration of a perpendicular magnetic recording medium according to a ninth embodiment of the present invention;

FIG. 16 is a cross-sectional diagram showing a configuration of a perpendicular magnetic recording medium according to a tenth embodiment of the present invention;

FIG. 17 is a cross-sectional diagram showing a configuration of a perpendicular magnetic recording medium according to an eleventh embodiment of the present invention;

FIG. 18 is a cross-sectional diagram showing a configuration of a perpendicular magnetic recording medium according to a twelfth embodiment of the present invention;

FIG. 19 is a graph illustrating the relationship between the average output and the recording layer film thickness in perpendicular magnetic media according to embodiments of the present invention; and

FIG. 20 is a diagram showing a configuration of a magnetic storage device according to a thirteenth embodiment of the present invention.

### DESCRIPTION OF THE PREFERRED EMBODIMENTS

In the following, preferred embodiments of the present invention are described with reference to the accompanying drawings.

### First Embodiment

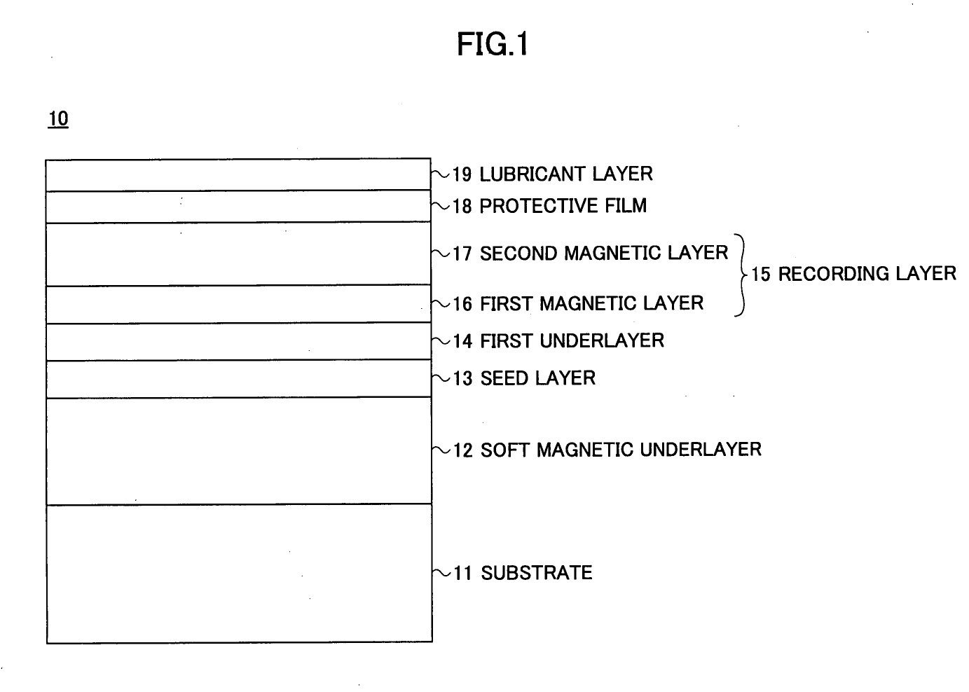

FIG. 1 is a cross-sectional diagram showing a configuration of a perpendicular magnetic recording medium according to a first embodiment of the present invention.

Referring to FIG. 1, the perpendicular magnetic recording medium 10 of the first embodiment includes a substrate 11 on which a soft magnetic underlayer 12, a seed layer 13, a first underlayer 14, a recording layer 15, a protective film 18, and a lubricant layer 19 are laminated in this order. The recording layer 15 includes a first magnetic layer 16 and a second magnetic layer 17 that are laminated in this order from the first underlayer 14 side.

The substrate 11 may correspond to a plastic substrate, a crystallized glass substrate, a tempered glass substrate, a Si substrate, or an aluminum alloy substrate, for example. In the case where the perpendicular magnetic recording medium 10 corresponds to a magnetic tape medium, a film made of polyester (PET), polyethylene (PEN), or polyimide (PI) with good thermal resistance, for example, may be used.

The soft magnetic layer 12 may be arranged to have a film thickness within a range of 50 nm˜2 μm, and may be made of a non-crystalline or microcrystalline magnetic material including at least one of the elements Fe, Co, Ni, Al, SI, Ta, Ti, Zr, Hf, V, Nb, C, or B, for example. It is noted that the soft magnetic underlayer 12 is not limited to a single layer structure, and plural layers may be laminated to form the soft magnetic underlayer 12.

Also, it is noted that the saturation flux density Bs of the soft magnetic material making up the soft magnetic underlayer 12 is preferably arranged to be at least 1.0 T in order to concentrate the recording magnetic field. For example, FeSi, FeAlSi, FeTaC, CoNbZr, CoCrNb, NiFeNb, or Co may be used as such soft magnetic material. The soft magnetic underlayer 12 preferably has high frequency magnetic permeability in order to realize high speed recording. The soft magnetic underlayer 12 may be formed through plating, sputtering, vapor deposition, or CVD (chemical vapor deposition), for example.

The seed layer 13 may be arranged to have a film thickness within a range of 1.0˜10 nm, and may be made of a non-crystalline material including at least one of Ta, Ti, C, Mo, W, Re, Os, Hf, Mg, Pt, or an alloy thereof, for example. Also, the seed layer 13 may be made of non-crystalline nonmagnetic NiP, for example. It is noted that the seed layer 13 is preferably made of a single-layer film with a film thickness within a range of 1.0˜5.0 nm in order to secure proximity between the soft magnetic underlayer 12 and the recording layer 15.

The first underlayer 14 may be arranged to have a film thickness within a range of 2˜14 nm, and may be made of Ru or Ru-M1 alloy (M1 corresponding to at least one of the elements Co, Cr, Fe, Ni, and Mn) having a hexagonal close packed (hcp) structure and including Ru as a main component, for example. The first underlayer 14 includes crystal grains 14a and a crystal grain boundary portion 14b formed at interfaces between adjacent crystal grains 14a. In other words, the first underlayer 14 corresponds to a polycrystalline body made of Ru or Ru-M1 alloy.

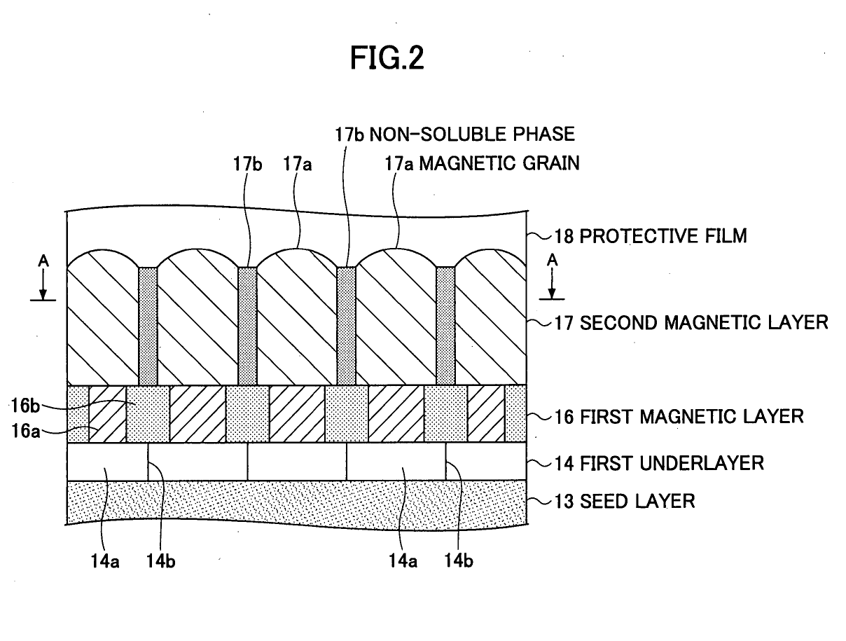

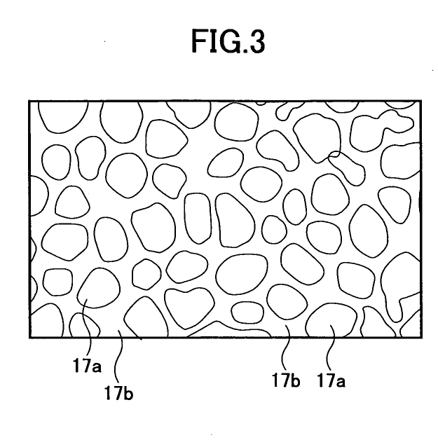

The first magnetic layer 16 and the second magnetic layer 17 each include magnetic grains (16a, 17a) made of hard magnetic material and a non-soluble phase (16b, 17b) made of nonmagnetic material, and are arranged into a so-called granular structure. In the following, crystal growth occurring at the first underlayer 14, the first magnetic layer 16, and the second magnetic layer 17 is described with reference to FIGS. 2 and 3.

FIG. 2 is a diagram showing a detailed structure of the perpendicular magnetic recording medium 10 shown in FIG. 1; and FIG. 3 is a cross-sectional view of the perpendicular magnetic recording medium 10 of FIG. 2 cut across line A-A.

Referring to FIGS. 2 and 3, the first underlayer 14 is made up of a sequence of crystal grains 14a that are bonded to each other via the crystal grain boundary portion 14b. In this way, good crystalline structure of the crystal grains 14a may be realized. Also, the (001) surfaces of the crystal grains 14a are arranged to be parallel with respect to the substrate surface. Accordingly, the crystalline structure and crystal orientation at the surface of the first underlayer 14 may be improved, and the crystalline structure and crystal orientation of the magnetic grains 16a of the first magnetic layer 16 that is epitaxially grown on the surface of the first underlayer 14 may be improved as well.

Also, it is noted that since the first underlayer 14 is formed on the non-crystalline seed layer 13, self-organization of the first underlayer 14 is induced and the crystal grains 14a are shaped into substantially the same size. Thus, the crystal grains 14a may be evenly arranged. Also, since the magnetic grains 16a of the first magnetic layer 16 are grown on the surface of crystal grains 14a of the first underlayer 14, the magnetic grains 16a may also be evenly arranged. In turn, the magnetic grains 17a of the second magnetic layer 17 that are formed on the first magnetic layer 16 may be evenly arranged as well. In this way, interaction between the magnetic grains 16a of the first magnetic layer 16 and interaction between the magnetic grains 17a of the second magnetic layer 17 may be prevented and medium noise may be reduced. It is noted that the magnetic grains 17a of the second magnetic layer 17 are preferably formed on the surfaces of the magnetic grains 16a of the first magnetic layer 16 on a one-to-one basis. In this way, the even arrangement of the magnetic gains 16a of the first magnetic layer 16 may be passed on to the second magnetic layer 17.

The first magnetic layer 16 and the second magnetic layer 17 respectively include column shaped magnetic grains 16a and 17a, and non-soluble phases 16b and 17b made of nonmagnetic material surrounding the magnetic grains 16a and 17a and physically segregating adjacent pairs of magnetic grains 16a and 17a. The non-soluble phases 16b and 17b are respectively filled into a space formed between the magnetic grains 16a and a space formed between the magnetic grains 17a.

As is shown in FIG. 3, in the second magnetic layer 17, the magnetic grains 17a are surrounded by the non-soluble phase 17b and are segregated from adjacent magnetic grains 17a by the non-soluble phase 17b. It is noted that the first magnetic layer 16 also has a structure similar to that of the second magnetic layer 17. The granular structures of the first magnetic layer 16 and the second magnetic layer 17 may be formed by inducing self-organization of the magnetic grains 16a and 17a in a sputtering process, for example. It is noted that each of the magnetic grains 16a and 17a are preferably arranged to have a single crystalline region structure; however, the magnetic grains 16a and 17a may include plural crystalline regions as well as crystal boundaries and crystal defects within one grain.

The magnetic grains 16a and 17a are made of hard magnetic material corresponding to one of Ni, Fe, Co, Ni alloy, Fe alloy, CoCr, CoPt, or CoCr alloy. The CoCr alloy may include CoCrTa, CoCrPt, CoCrPt-M2, for example. Herein, M2 may correspond to the elements B, Mo, Nb, Ta, W, Cu, or alloys thereof. The magnetic grains 16a and 17a have easy magnetization axes that are substantially perpendicular to the substrate surface. For example, in a case where the hard magnetic material of the magnetic grains 16a and 17a has a hcp structure, the magnetic grains 16a and 17a are oriented such that their c axes are substantially perpendicular to the substrate.

In the case where the magnetic grains 16a and 17a are made of CoCrPt-M2, the Co content is arranged to make up 50˜80 atomic % of the material, the Pt component is arranged to make up 15˜30 atomic % of the material, the M2 concentration is arranged to be greater than 0 atomic % but no more than 20 atomic %, and the remainder of the material content is arranged to correspond to Cr. In the present embodiment, the Pt content is arranged to be greater than that of conventional perpendicular magnetic recording media so that the anisotropic magnetic field may be increased and coercive force in the perpendicular direction with respect to the substrate may be increased.

The non-soluble phases 16b and 17b are made of nonmagnetic material that does not dissolve nor form compounds with the hard magnetic material making up the magnetic grains 16a and 17a. The nonmagnetic material corresponds to a compound that is made up of one of the elements Si, Al, Ta, Zr, Y, Ti and Mg, and at least one of the elements O, N, and C. The nonmagnetic material includes oxides such as SiO₂, Al₂O₃, Ta₂O₅, ZrO₂, Y₂O₃, TiO₂, and MgO, nitrides such as Si₃N₄, AlN, TaN, ZrN, TiN, and Mg₃N₂, and carbides such as SiC, TaC, ZrC, and TiC, for example. By providing the non-soluble phases 16b and 17b made of a nonmagnetic material, adjacent magnetic grains 16a/17a may be physically segregated from each other. In this way, magnetic interaction between the magnetic grains 16a/17a may be reduced, and in turn, medium noise may be reduced.

Also, it is noted that the nonmagnetic material making up the non-soluble phase 16b/17b preferably corresponds to insulating material. In this way, a tunnel effect may be prevented from occurring in electrons realizing the hard magneticity, and exchange interaction between the magnetic grains 16a/17a may be reduced.

The atomic concentration of the non-soluble phase 16b of the first magnetic layer 16 is preferably arranged to be within a range of 10˜20 atomic %, and more preferably within a range of 13˜20 atomic %. It is noted that when the atomic concentration Y1 of the non-soluble phase 16b is less than 10 atomic %, the magnetic grains 16a may easily bond with one another. When the atomic concentration Y1 of the non-soluble phase 16b exceeds 20 atomic %, the atomic concentration of the magnetic grains 16a may be decreased to a level that may cause degradation of the reproducing output. The atomic concentration Y1 of the non-soluble phase 16b may be expressed as follows:
Y1=M_{Y1}/(M_{X1}+M_{Y1})×100 [atomic %]
wherein M_{X1} represents the number of atoms making up the magnetic grains 16a of the first magnetic layer 16, and M_{Y1} represents the number of atoms making up the non-soluble phase 16b of the first magnetic layer 16.

It is further noted that the atomic concentration Y1 of the non-soluble phase 16b of the first magnetic layer 16 is more preferably set within a range of 12˜15 atomic %. When the atomic concentration Y1 of the non-soluble phase 16b exceeds 15 atomic %, the growth direction of the magnetic grains 16a may be easily shifted from a direction perpendicular to the substrate surface to a direction parallel to the substrate surface.

The atomic concentration Y2 of the non-soluble phase 17b of the second magnetic layer 17 is preferably set within a range of 5˜15 atomic %, and more preferably within a range of 9˜13 atomic %. When the atomic concentration Y2 of the non-soluble phase 17b is less than 5 atomic %, the magnetic grains 17a may easily bond with one another, and the magnetic grains 17a may not be sufficiently segregated. When the atomic concentration Y2 of the non-soluble phase 17b exceeds 15 atomic %, the atomic concentration Y2 of the magnetic grains 17a may be decreased to a level that may cause degradation of the reproducing output. The atomic concentration Y2 of the non-soluble phase 16b may be expressed as follows:
Y2=M_{Y2}/(M_{X2}+M_{Y2})×100 [atomic %]
wherein M_{X2} represents the number of atoms making up the magnetic grains 17a of the second magnetic layer 17, and M_{Y2} represents the number of atoms making up the non-soluble phase 17b of the second magnetic layer 17.

Further, it is noted that the atomic concentration Y1 of the non-soluble phase 16b of the first magnetic layer 16 is preferably arranged to be higher than the atomic concentration Y2 of the non-soluble phase 17b of the second magnetic layer 17 (i.e., Y1>Y2). In this way, the magnetic grains 16a may be effectively segregated at the first magnetic layer 16, and since the magnetic grains 17a of the second magnetic layer 17 is formed on (grown from) the surface of the magnetic grains 16a of the first magnetic layer 16, the magnetic grains 17a may also be effectively segregated. In other words, even if the atomic concentration Y2 of the non-soluble phase 17b of the second magnetic layer 17 is set lower than the atomic concentration Y1 of the non-soluble phase 16b of the first magnetic layer 16, the magnetic grains 17a may still be effectively segregated. It believed that such an effect is achieved owing to the fact that the magnetic grains 16a of the first magnetic layer 16 function as the nuclei of crystal growth of the magnetic grains 17a.

Also, it is noted that the saturation flux density of the second magnetic layer 17 is preferably arranged to be higher than the saturation flux density of the first magnetic layer 16. The playback output level of a magnetic head is determined by calculating the product of the remnant flux density and the film thickness for each of the first magnetic layer 16 and the second magnetic layer 17 and obtaining the sum of the products. By arranging the saturation flux density of the second magnetic layer 17 to be higher than the saturation flux density of the first magnetic layer 16, the remnant flux density of the second magnetic layer 17 may be higher than the remnant flux density of the first magnetic layer 16 compared to a case in which the first magnetic layer 16 and the second magnetic layer 17 are arranged to have the same saturation flux density. Accordingly, a predetermined playback output level may be achieved by the film thickness of the second magnetic layer 17 corresponding to the thinner magnetic layer. Therefore, the overall thickness of the recording layer 15 may be reduced, and the distance from a recording/playback element (not shown) of the magnetic head to the surface of the soft magnetic underlayer 12 may be reduced. As a result, spacing loss occurring upon playback may be reduced to realize a higher output.

The film thickness of the first magnetic layer 16 is preferably arranged to be within a range of 1˜4 nm, and more preferably within a range of 2˜3 nm. The film thickness of the second magnetic layer 17 is preferably arranged to be within a range of 6˜10 nm, and more preferably within a range of 6˜8 nm. Also, the first magnetic layer 16 is preferably arranged to be thinner than the second magnetic layer 17. In this way, the reproducing output may be secured while preventing the increase of the overall film thickness of the recording layer 15.

For example, the first magnetic layer 16 and the second magnetic layer 17 may be arranged such that the magnetic grains 16a and 17a are made of CoCrPt-M2, and the non-soluble phases 16b and 17b are made of SiO₂. In this example, the atomic concentration of the SiO₂ non-soluble phase 16b of the first magnetic layer 16 is preferably arranged to be within a range of 10˜20 atomic %, and the atomic concentration of the SiO₂ non-soluble phase 17b of the second magnetic layer 17 is preferably arranged to be within a range of 5˜15 atomic %. Further, the dosage rate of the non-soluble phase 16b within the first magnetic layer 16 is preferably arranged to be higher than the dosage rate of the non-soluble phase 17b within the second magnetic layer 17.

Referring back to FIG. 1, the protective film 18 may be arranged to have a film thickness within a range of 0.5˜15 nm, and may be made of amorphous carbon, carbon hydride, carbon nitride, or aluminum oxide, for example. It is noted that the protective film 18 is not limited to a particular type of material.

The lubricant layer 19 may be arranged to have a film thickness within a range of 0.5˜5 nm, and may be formed by a lubricant with perfluoropolyether constituting the main chain, for example. In one specific example, perfluoropolyether terminated by an OH end group or a piperonyl end group may be used as the lubricant. It is noted that the lubricant layer 19 may be provided or omitted depending on the material used as the protective film 18.

In the following, a method for manufacturing the perpendicular magnetic recording medium 10 according to the first embodiment is described with reference to FIG. 1.

First, after the surface of the substrate 11 is cleaned and dried, the soft magnetic underlayer 12 is formed on the substrate 11 through non-electro plating, electro plating, sputtering, or vacuum deposition, for example.

Then, a sputtering apparatus is used to form a seed layer 13 on the soft magnetic underlayer 12. In a specific example, DC magnetron sputtering is conducted using a sputtering target made of the nonmagnetic material of the seed layer 13 as is indicated above, and setting Ar gas to an atmospheric pressure of 0.4 Pa to form the seed layer 13. It is noted that the substrate 11 is preferably not heated during this film deposition process. In this way, crystallization or enlargement of micro-crystals in the soft magnetic underlayer 12 may be prevented. Alternatively, the substrate 11 may be heated to a temperature that may not induce crystallization or enlargement of micro-crystals in the soft magnetic underlayer 12 (e.g., a temperature of less than or equal to 150° C.). Also, the substrate 11 may be cooled to a temperature below room temperature such as −100° C. (or lower if cooling restrictions are not imposed in the apparatus). It is noted that similar heating and/or cooling processes of the substrate 11 may be conducted in the formation of the first magnetic layer 16 and the second magnetic layer 17. Also, in a preferred embodiment, gas is evacuated from the sputtering apparatus to a pressure of 10⁻⁷ Pa before conducting the film deposition process, and atmospheric gas such as Ar gas is supplied to the apparatus thereafter.

Then, the sputtering apparatus is used to form the first underlayer 14 on the seed layer 13. In a specific example, DC magnetron sputtering is conducted in an inactive gas atmosphere such as a Ar gas atmosphere using a sputtering target that is made of Ru or Ru-M1 alloy as is described above to form the first underlayer 14. It is noted that the first underlayer 14 may be formed at a deposition speed that is greater than 2 nm/s but less than or equal to 8 nm/s, for example, or the first underlayer 14 may be formed in an inactive gas atmosphere with a pressure that is greater than or equal to 0.26 Pa but less than 2.6 Pa (more preferably within a range of 0.26˜1.33 Pa), for example. By setting the atmospheric pressure or the deposition speed to the ranges indicated above, the first underlayer 14 that has a polycrystalline structure realized by the crystal grains 14a and the crystal boundaries 14b as is described above may be formed. It is noted that the first underlayer 14 may also be formed through RF magnetron sputtering instead of DC magnetron sputtering.

Then, the sputtering apparatus is used to successively form the first magnetic layer 16 and the second magnetic layer 17 on the first underlayer 14 using sputtering targets made of a hard magnetic material and a nonmagnetic material. In a specific example, RF magnetron sputtering is conducted in an inactive gas atmosphere set to an atmospheric pressure of 2.00˜8.00 Pa (more preferably 2.00˜3.99 Pa) using a composite sputtering target made of the hard magnetic material and the nonmagnetic material of the first magnetic layer 16 to form the first magnetic layer 16. Then, a similar process is conducted using a composite sputtering target made of the hard magnetic material and the nonmagnetic material of the second magnetic layer to form the second magnetic layer 17 on the first magnetic layer 16. It is noted that in a case where the nonmagnetic material of the first magnetic layer 16 and the second magnetic layer 17 includes oxygen, oxygen gas may be added to the inactive gas; and in a case where the nonmagnetic material includes nitrogen, nitrogen gas may be added to the inactive gas.

The compositions of the sputtering targets used for forming the first magnetic layer 16 and the second magnetic layer 17 may be arranged to substantially correspond to the compositions of the first magnetic layer 16 and the second magnetic layer 17, respectively. However, it is noted that the compositions of the first magnetic layer 16 and the second magnetic layer 17 may slightly change from the compositions of their corresponding sputtering targets depending on film formation conditions. According to estimations made by the inventor of the present invention, a composition change of around 1 atomic % may occur with respect to the atomic concentrations Y1 and Y2 of the non-soluble phases 16b and 17b, and the deposited first magnetic layer 16 and the second magnetic layer 17 may have reduced atomic concentrations Y1 and Y2 of the non-soluble phases 16b and 17b with respect to their corresponding sputtering targets.

It is noted that in another embodiment, the first magnetic layer 16 and the second magnetic layer 17 may be formed by simultaneously sputtering a sputtering target made of hard magnetic material and a sputtering target made of nonmagnetic material.

Then, the protective film 18 is formed on the second magnetic layer 17 through sputtering, CVD, or FCA (Filtered Cathodic Arc), for example.

It is noted that in the process steps from forming the seed layer 12 to forming the protective film 18, a vacuum state or an inactive gas atmosphere is preferably maintained so that the layers being formed may have clean surfaces.

Then, the lubricant layer 19 is formed on the surface of the protective film 18. The lubricant layer 19 may be formed by applying a diluted lubricant solution in an immersion or spin coating process, for example. In this way, the perpendicular magnetic recording medium 10 of the present embodiment may be formed.

According to the present embodiment, the first underlayer 14 is formed on the non-crystalline seed layer 13, and thereby, self-organization of the first underlayer 14 may be induced, and crystal grains 14a of a substantially uniform size may be formed. In this way, the crystal grains 14a may be evenly arranged. Also, since the magnetic grains 16a and 17a of the first magnetic layer 16 and the second magnetic layer 17 are grown on the surfaces of the crystal grains 14a of the first underlayer 14, the magnetic grains 16a and 17a may be evenly arranged as well. In this way, interaction between the magnetic grains 16a of the first magnetic layer 16 and interaction between the magnetic grains 17 a of the second magnetic layer 17 may be prevented, and medium noise of the perpendicular magnetic recording medium 10 may be reduced so that the S/N ratio may be improved.

Also, according to the present embodiment, the crystal grains 14a of the first underlayer 14 is made of Ru or Ru-M1 alloy having a hcp structure and containing Ru as a main component. By arranging the first underlayer 14 to be made of Ru or Ru-M1 alloy, good lattice compatibility may be realized with respect to the magnetic grains 16a of the first magnetic layer 16, and the crystalline structure of the first magnetic layer 16 and the second magnetic layer 17 may be improved. In turn, the coercive force and the saturation flux density of the first magnetic layer 16 and the second magnetic layer 17 may be improved.

Further, since the atomic concentration of the non-soluble phase (nonmagnetic material) in the first magnetic layer 16 is arranged to be higher than that in the second magnetic layer 17, the magnetic grains 16a of the first magnetic layer 16 may be sufficiently segregated by the non-soluble phase 16b. Specifically, in the first magnetic layer 16, bonding of the magnetic grains 16a may be prevented by the non-soluble phase 16b. In the second magnetic layer 17, the magnetic grains 17a are grown on the magnetic grains 16a of the first magnetic layer 16, and thereby, the magnetic grains 17a of the second magnetic layer 17 may be segregated from each other as well. By segregating the magnetic grains 17a of the second magnetic layer 17 from one another, interaction between the magnetic grains 17a may be prevented and medium noise of the perpendicular magnetic recording medium may be reduced. As can be appreciated from the above descriptions, a perpendicular magnetic recording medium with reduced noise, an improved S/N ratio, and high density recording capabilities may be realized according to the present embodiment.

### Second Embodiment

In the following, a perpendicular magnetic recording medium 20 according to a second embodiment of the present invention is described. The perpendicular magnetic recording medium 20 of the present embodiment includes a second underlayer 21 provided between a first underlayer 14 and a recording layer 15. It is noted that other features of the perpendicular magnetic recording medium 20 of the second embodiment are identical to those of the first embodiment.

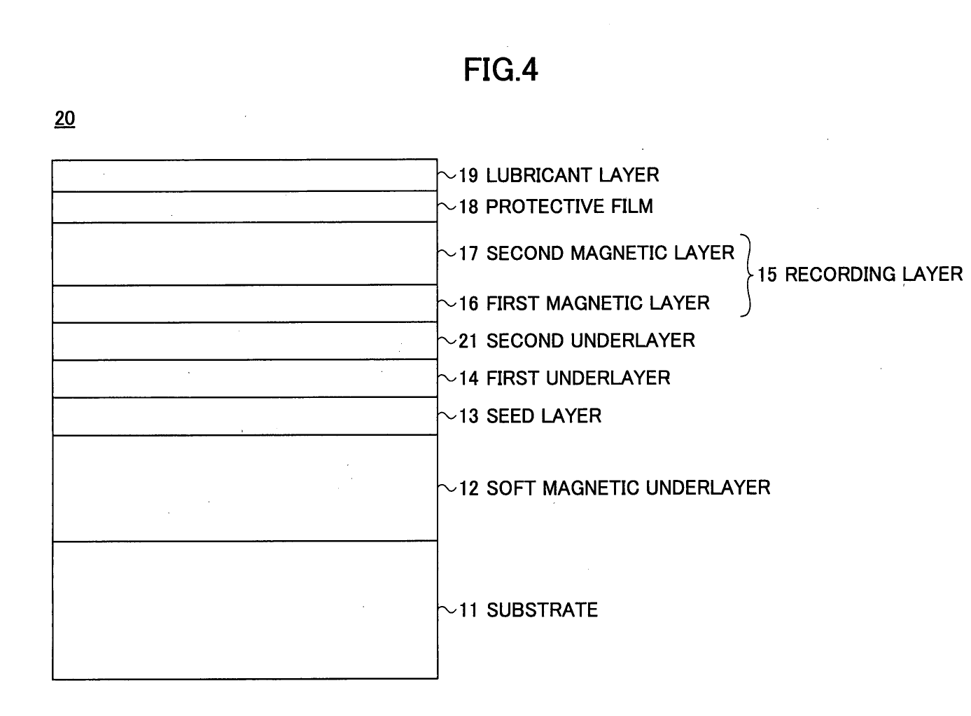

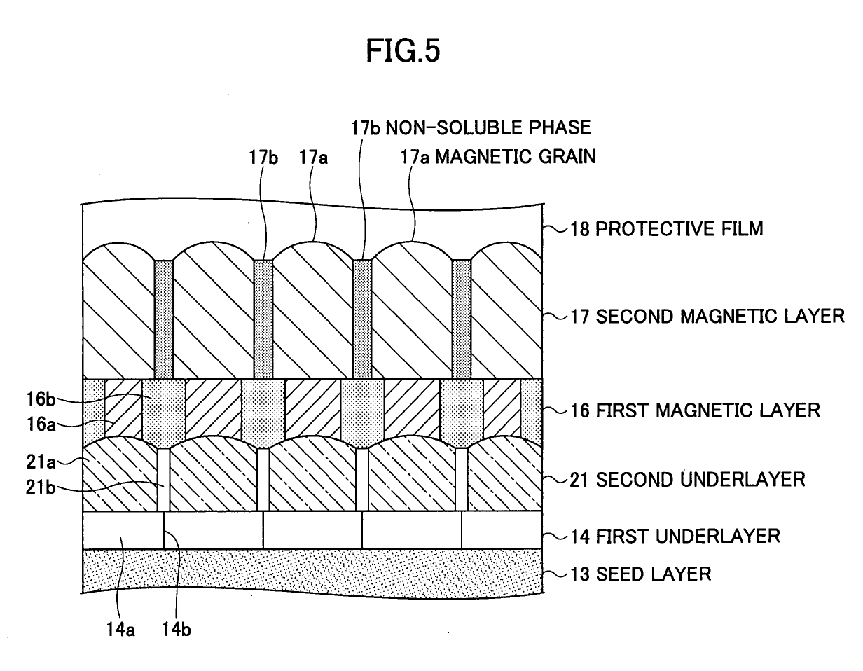

FIG. 4 is a cross-sectional diagram showing a configuration of the perpendicular magnetic recording medium 20 according to the second embodiment. FIG. 5 is a diagram showing a more detailed configuration of the perpendicular magnetic recording medium 20 shown in FIG. 4. It is noted that in FIGS. 4 and 5, components that are identical to those described in relation to the first embodiment are given the same references and their descriptions are omitted.

Referring to FIGS. 4 and 5, the perpendicular magnetic recording medium 20 of the present embodiment includes a substrate 11 on which a soft magnetic underlayer 12, a seed layer 13, a first underlayer 14, a second underlayer 21, a recording layer 15, a protective film 18, and a lubricant layer 19 are laminated in this order. The recording layer 15 includes a first magnetic layer 16 and a second magnetic layer 17.

The second underlayer 21 includes plural crystal grains 21a and a void portion 21b segregating the crystal grains 21a from each other. The void portion 21b corresponds to a portion at which the density of the material making up the second underlayer 21 is particularly low. It is believed that atmospheric gas used in the film formation process is filled in the void portion 21b. The crystal grains 21a are grown from the surfaces of the crystal grains 14a of the first underlayer 14 in a substantially perpendicular direction with respect to the substrate surface and are arranged into column structures extending towards the interface with the first magnetic layer 16. It is noted that each of the crystal grains 21a may be made of one or more single crystals.

The second underlayer 21 is arranged to have a film thickness within a range of 2˜16 nm, and is made of Ru or Ru-M1 alloy (M1 corresponding to at least one of the elements CO, Cr, Fe, Ni, and Mn) having a hcp structure and including Ru as a main component. It is noted that when the second underlayer 21 is thinner than 2 nm, its crystalline structure may be degraded, and when the second underlayer 21 is thicker than 16 nm, its crystal orientation may be degraded and defects such as blurring may occur upon recording. The second underlayer 21 is preferably arranged to have a film thickness within a range of 3˜16 nm to induce isolation of the crystal grains 21a, and more preferably within a range of 3˜10 nm to prevent spacing loss.

By using a material having a hcp structure such as Ru or Ru-M1 alloy for the second underlayer 21, the easy magnetization axis of the magnetic grains 16a may be oriented in a substantially perpendicular direction with respect to the substrate surface if the magnetic grains 16a of the first magnetic layer 16 have a hcp structure. Further, it is noted that the second underlayer 21 is preferably made of Ru to realize good crystal growth.

As is shown in FIG. 5, in the second underlayer 21, the void portion 21b is arranged to surround the crystal grains 21a. The void portion 21b may be arranged to have a substantially uniform width from the bottom surface of the crystal grain 21a to the interface with the first magnetic layer 16. In another example, the void portion may be arranged to widen in the direction towards the interface with the first magnetic layer 16. According to evaluations made by the present inventor, when the perpendicular magnetic recording medium 20 of the present embodiment is manufactured according to a manufacturing method described below, it may be observed from a TEM image of the cross section of the manufactured perpendicular magnetic recording medium 20 that regions surrounding the upper half portion of the crystal grains 21a tend to form a larger void compared to the regions surrounding the lower half portion of the crystal grains 21a. By providing the second underlayer 21, the magnetic grains 16a of the first magnetic layer 16 that are formed on the surface of the crystal grains 21a may be suitably segregated from one another. Also, the crystalline structure of the magnetic grains 16a of the first magnetic layer 16 in the perpendicular magnetic recording medium 20 of the present embodiment may be improved compared to the first embodiment, and the good crystalline structure realized in the magnetic grains 16a of the first magnetic layer 16 may be carried on to the magnetic grains 17a of the second magnetic layer 17. In this way, the S/N ratio of the perpendicular magnetic recording medium 20 according to the present embodiment may be further improved from that of the first embodiment.

In the following, a method of forming the second underlayer 21 is described. It is noted that methods for forming other layers of the perpendicular magnetic recording medium 20 are identical to the methods for forming the layers of the perpendicular magnetic recording medium 10 of the first embodiment as is described above, and thereby their descriptions are omitted.

A sputtering apparatus is used to apply a sputtering target made of Ru or Ru-M1 alloy as is described above to form the second underlayer 21 on the first underlayer 14. In a specific example, the second underlayer 21 may be formed by conducting DC magnetron sputtering in an inactive gas atmosphere such as an Ar atmosphere at a deposition speed of 0.1˜2 nm/s and at an atmospheric gas pressure of 2.66˜26.6 Pa. By setting the deposition speed and the atmospheric gas pressure to be within the ranges indicated above, the second underlayer 21 with the crystal grains 21a and the void portion 21b as is described above may be formed.

It is noted that when the deposition speed is lower than 0.1 nm/s, the manufacturing efficiency is significantly degraded, and if the deposition speed is higher than 2 nm/s, the void portion 21b may not be formed so that the formed layer may correspond to a continuing sequence of crystal grains and crystal boundary portions. Also, it is noted that when the inactive gas pressure is lower than 2.66 Pa, the the void portion 21b may not be formed so that the formed layer may correspond to a continuing sequence of crystal grains and crystal boundary portions, and when the inactive gas pressure is higher than 26.6 Pa, the inactive gas may be introduced into the crystal grains and the crystalline structure of the crystal grains may be degraded. Further, the substrate 11 is preferably not heated upon forming the second underlayer 21 in order to prevent crystallization or enlargement of micro-crystals in the soft magnetic underlayer 12.

It is noted that the advantageous effects of the perpendicular magnetic recording medium 10 of the first embodiment may similarly be realized in the perpendicular magnetic recording medium 20 of the present embodiment. The perpendicular magnetic recording medium 20 of the present embodiment includes the second underlayer 21 formed by the crystal grains 21a and the void portion 21b in between the first underlayer 14 and the first magnetic layer 16. The crystal grains 21a are segregated from each other by the void portion 21b so that the magnetic grains 16a of the first magnetic layer 16 that are grown on the surfaces of the crystal grains 21a may also be segregated from one another. In turn, the magnetic grains 17a of the second magnetic layer 17 that are grown on the surfaces of the magnetic grains 16a of the first magnetic layer 16 may also be segregated from each other. By providing the second underlayer 21, the crystalline structure of the magnetic grains 16a of the first magnetic layer 16 may be improved, and the improved crystalline structure may be carried on to the magnetic grains 17a of the second magnetic layer 17. Thereby, medium noise of the perpendicular magnetic recording medium 20 may be further reduced compared with the perpendicular magnetic recording medium 10 of the first embodiment. In this way, a perpendicular magnetic recording medium with a further improved S/N ratio may be realized.

### Third Embodiment

In the following, a perpendicular magnetic recording medium 30 according to a third embodiment of the present invention is described. The perpendicular magnetic recording medium 30 of the present embodiment includes a recording layer 35 that includes first through n^{th} magnetic layers. It is noted that other features of the perpendicular magnetic recording medium 30 according to the present embodiment are generally identical to those of the perpendicular magnetic recording medium 10 of the first embodiment.

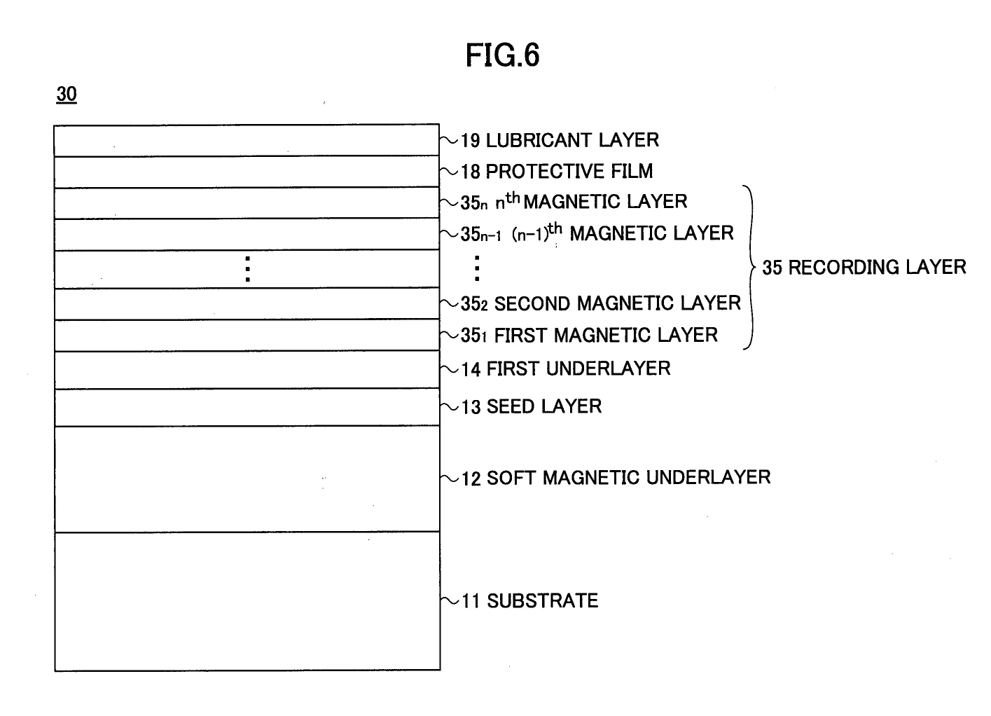

FIG. 6 is a cross-sectional diagram showing a configuration of the perpendicular magnetic recording medium 30 according to the third embodiment. In this drawing, components that are identical to those described in relation to the first embodiment are given the same references and their descriptions are omitted.

Referring to FIG. 6, the perpendicular magnetic recording medium 30 includes a substrate 11 on which a soft magnetic underlayer 12, a seed layer 13, a first underlayer 14, a recording layer 35, a protective film 18, and a lubricant layer 19 are laminated in this order. The recording layer 35 includes a first magnetic layer 35₁, a second magnetic layer 35₂, . . . , a (n−1)^{th} magnetic layer 35ₙ₋₁, and a n^{th} magnetic layer 35ₙ that are laminated in this order. In this example, n corresponds to an integer that is greater than or equal to 3.

The first magnetic layer 35₁ through the n^{th} magnetic layer 35ₙ may be made of any of the materials of the first magnetic layer 16 and the second magnetic layer 17 described above. The first magnetic layer 35₁ through the (n−1)^{th} magnetic layer 35ₙ₋₁ are arranged such that the atomic concentrations of their corresponding non-soluble phases are set higher than the second magnetic layer 35₂ through the n^{th} magnetic layer 35ₙ, respectively, that are deposited directly on top of the above magnetic layers. In other words, the atomic concentrations of the non-soluble phases of the first magnetic layer 35₁ through the n^{th} magnetic layer 35ₙ are arranged to decrease in the direction from the first magnetic layer 35₁ to the n^{th} magnetic layer 35ₙ. For example, as is described in relation to the first embodiment, the atomic concentration Y1 of the non-soluble phase of the first magnetic layer 35₁ is arranged to be higher than the atomic concentration Y2 of the non-soluble phase of the second magnetic layer 35₂. Given that the atomic concentration of the non-soluble phase of a k^{th} magnetic layer is expressed as Yk (k=1˜n), the atomic concentrations Y1˜Yn of the respective non-soluble phases of the first magnetic layer 35₁ through the n^{th} magnetic layer 35ₙ are set such that Y1>Y2> . . . >Yn. By arranging the atomic concentrations of the non-soluble phases of the first magnetic layer 35₁ through the n^{th} magnetic layer 35ₙ in this manner, the magnetic grains in each of the first magnetic layer 35₁ through the n^{th} magnetic layer 35ₙ may be effectively segregated from one another, and the overall atomic concentration of the magnetic grains within the recording layer 35 may be increased compared to the recording layer 15 of the perpendicular magnetic recording medium 10 according to the first embodiment. Accordingly, in one aspect, the reproducing output of the perpendicular magnetic recording medium 30 may be increased and the medium noise may at least be maintained (i.e., not increased) so that the S/N ratio may be further improved compared to the perpendicular magnetic recording medium 10 of the first embodiment. In another aspect, the film thickness of the recording layer 35 may be decreased while maintaining the reproducing output of the perpendicular magnetic recording medium 30.

It is noted that the film thickness of the recording layer 35, that is, the total of the film thicknesses of the first magnetic layer 35₁ through the n^{th} magnetic layer 35ₙ, is preferably arranged to be within a range of 9˜16 nm.

In the following a method for forming the recording layer 35 is described. It is noted that the methods for forming the layers of the perpendicular magnetic recording medium 30 other than the recording layer 35 are identical to the methods described above for forming the layers of the perpendicular magnetic recording medium 10 of the first embodiment. According to one example, the recording layer 35 may be formed in a manner similar to that of the first embodiment using sputtering targets having compositions corresponding to the respective compositions of the first magnetic layer 35₁ through the n^{th} magnetic layer 35ₙ. In another example, a sputtering target made of hard magnetic material and a sputtering target made of nonmagnetic material may be used, and the sputtering charge powers for the respective sputtering targets may be suitably controlled for forming each of the first magnetic layer 35₁ through the n^{th} magnetic layer 35ₙ.

It is noted that the advantageous effects of the perpendicular magnetic recording medium 10 of the first embodiment may similarly be realized in the perpendicular magnetic recording medium 30 of the present embodiment. Additionally, in one aspect of the present embodiment, the reproducing output may be increased and the medium noise may be at least maintained in the perpendicular magnetic recording medium 30 so that the S/N ratio may be further improved. In another aspect of the present embodiment, the film thickness of the recording layer 35 may be reduced while maintaining the reproducing output so that the so-called magnetic spacing (i.e., distance between the soft magnetic underlayer 12 and the recording/reproducing element of the magnetic head) may be reduced. In this way, the S/N ratio may be improved further and blurring may be prevented in the perpendicular recording medium 30 according to the present embodiment.

### Fourth Embodiment

In the following, a perpendicular magnetic recording medium 40 according to a fourth embodiment of the present invention is described. The perpendicular magnetic recording medium 40 according to the present embodiment has a structure that is generally identical to that of the perpendicular magnetic recording medium 30 according to the third embodiment; however, the perpendicular magnetic recording medium 40 of the present embodiment includes a second underlayer 21 in between a first underlayer 14 and a recording layer 35. In other words, the perpendicular magnetic recording medium 40 according to the present embodiment has the combined features of the second embodiment and the third embodiment described above.

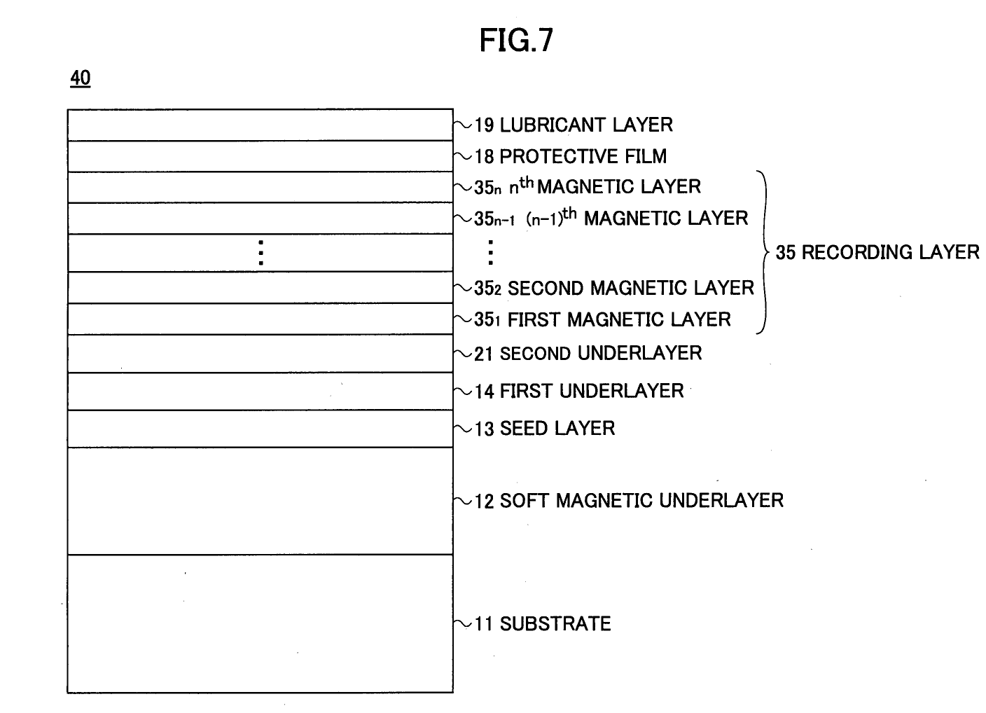

FIG. 7 is a cross-sectional diagram showing a configuration of the perpendicular magnetic recording medium 40 according to the fourth embodiment. In this drawing, components that are identical to those described in relation to the first through third embodiments are given the same references and their descriptions are omitted.

Referring to FIG. 7, the perpendicular magnetic recording medium 40 includes a substrate 11 on which a soft magnetic underlayer 12, a seed layer 13, a first underlayer 14, a second underlayer 21, a recording layer 35, a protective film 18, and a lubricant layer 19 are laminated in this order. The recording layer 35 includes a first magnetic layer 35₁, a second magnetic layer 35₂, . . . , a (n−1)^{th} magnetic layer 35ₙ₋₁, and a n^{th} magnetic layer 35ₙ that are laminated in this order. In this example, n corresponds to an integer that is greater than or equal to 3.

By providing the second underlayer 21 in the perpendicular magnetic recording medium 40, the crystalline structure of the magnetic grains of the magnetic layers 35₁˜35ₙ making up the recording layer 35 may be further improved. Also, by providing the second underlayer 21, the magnetic grains of the first magnetic layer 35₁ may be adequately segregated from one another. In turn, such an arrangement of the magnetic grains may be passed on to the second magnetic layer 35₂ and onward up to the n^{th} magnetic layers 35ₙ. Therefore, a combination of the advantageous effects of the second embodiment and the third embodiment described above may be realized in the perpendicular magnetic recording medium 40 of the present embodiment. In this way, the S/N ratio may be further improved in the perpendicular magnetic recording medium 40 of the present embodiment.

### Fifth Embodiment

In the following, a perpendicular magnetic recording medium 50 according to a fifth embodiment of the present invention is described. The perpendicular magnetic recording medium 50 according to the present embodiment includes a recording layer 55 that corresponds to a composition modulated film. It is noted that other features of the perpendicular magnetic recording medium according to the present embodiment are identical to those of the perpendicular magnetic recording medium 10 according to the first embodiment.

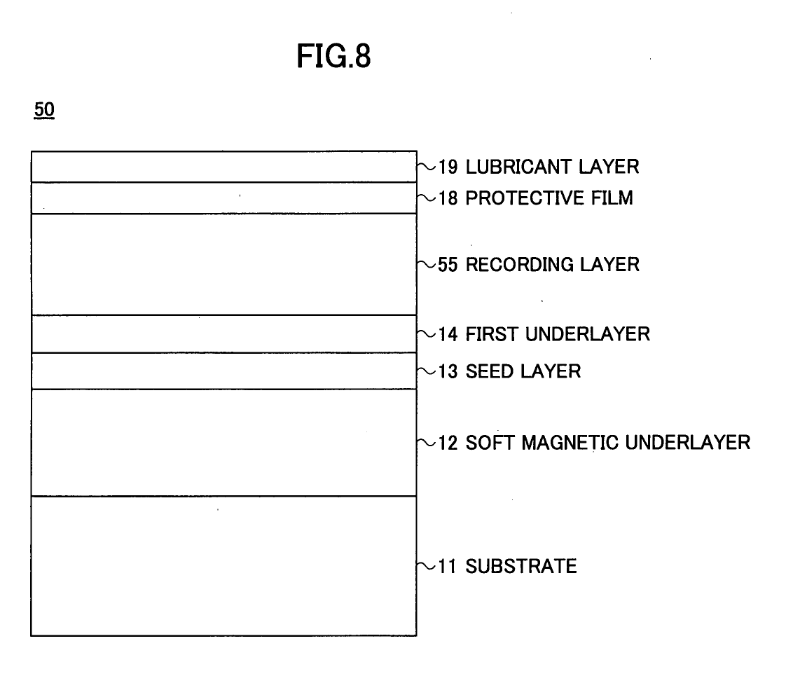

FIG. 8 is a cross-sectional diagram showing a configuration of the perpendicular magnetic recording medium 50 according to the fifth embodiment. In this drawing, components that are identical to those described in relation to the first embodiment are given the same references and their descriptions are omitted.

Referring to FIG. 8, the perpendicular magnetic recording medium 50 includes a substrate 11 on which a soft magnetic underlayer 12, a seed layer 13, a first underlayer 14, a recording layer 55, a protective film 18, and a lubricant layer 19 are laminated in this order.

The recording layer 55 may be made of any of the materials of the first magnetic layer 16 and the second magnetic layer 17 described above, and corresponds to a so-called composition modulated film in which the atomic concentration of the non-soluble phase within this recording layer 55 gradually decreases in the direction from the first underlayer 14 to the protective film 18. In other words, in the recording layer 55, the atomic concentration of the non-soluble phase at the interface with the first underlayer 14 is set relatively high, and the atomic concentration of the non-soluble phase is gradually lowered as the layer progresses towards the protective film 18. By arranging the recording layer 55 in this manner, the magnetic grains of the recording layer 55 may be segregated from one another at the interface with the first underlayer 14. According to the present embodiment, the grain diameter of each of the magnetic grains of the recording layer 55 is arranged to gradually increase as the layer progresses from the interface with the first underlayer 14 towards the protective layer 18. In this case, since the magnetic grains are segregated at their base, bonding of the magnetic grains may be effectively prevented throughout the film thickness direction of the recording layer 55. Thus, the magnetic grains of the recording layer 55 may be segregated from each other. Also, since the volume ratio of the non-soluble phase (i.e., nonmagnetic material) within the recording layer 55 continually changes, the atomic concentration of the magnetic grains in the recording layer may be increased compared to the first embodiment. Accordingly, in one aspect of the present embodiment, the reproducing output may be increased, and the medium noise may at least be maintained so that the S/N ratio may be further improved in the perpendicular magnetic recording medium 50. According to another aspect of the present embodiment, the film thickness of the recording layer 55 may be reduced while maintaining the reproducing output in the perpendicular magnetic recording medium 50.

The recording layer 55 is preferably arranged such that its composition at a region close to the interface with the first underlayer 14 includes the non-soluble phase at an atomic concentration of 10˜20 atomic %, and its composition at a region close to the interface with the protective film 18 includes the non-soluble phase at an atomic concentration of 5˜15 atomic %. It is noted that the composition of the recording layer 55 at the region close to the interface with the first underlayer 14 may be arranged such that its atomic concentration of the non-soluble phase is set higher than the atomic concentration of the non-soluble phase in the first magnetic layer 16 of the perpendicular magnetic recording medium 10 according to the first embodiment. Also, the composition of the recording layer 55 at the region close to the interface with the protective film 18 may be arranged such that its atomic concentration of the non-soluble phase is set lower than the atomic concentration of the non-soluble phase in the second magnetic layer 21 of the perpendicular magnetic recording medium 10 according to the first embodiment. By arranging the recording layer 55 in this manner, bonding of the magnetic grains of the recording layer 55 may be prevented while maintaining the reproducing output. According to another aspect, as is described in relation to the fourth embodiment, the film thickness of the recording layer 55 may be reduced while maintaining the reproducing output.

In the following, a method for forming the recording layer 55 is described. It is noted that methods for forming the other layers of the perpendicular magnetic recording medium 50 are identical to the methods described above for forming the layers of the perpendicular magnetic recording medium 10 of the first embodiment.

The recording layer 55 is formed using a sputtering target made of hard magnetic material for the magnetic grains and a sputtering target made of nonmagnetic material for the non-soluble phase, and controlling the sputtering charge powers for the respective sputtering targets. In one specific example, the sputtering charge power for the sputtering target made of hard magnetic material may be fixed, and the sputtering charge power for the sputtering target made of nonmagnetic material may be gradually decreased as the layer progresses from the interface with the first underlayer 14 towards the interface with the protective film 18.

It is noted that the advantageous effects of the first embodiment may similarly be realized in the perpendicular magnetic recording medium 50 according to the present embodiment. Additionally, in one aspect of the present embodiment, the reproducing output may be increased and the medium noise may at least be maintained so that the S/N ratio may be further improved in the perpendicular magnetic recording medium 50. In another aspect of the present embodiment, the film thickness of the recording medium 55 may be reduced while maintaining the reproducing output in the perpendicular magnetic recording medium 50 so that the so-called magnetic spacing (i.e., distance between the soft magnetic underlayer 12 and the recording/reproducing element of the magnetic head) may be reduced. In this way, the S/N ratio may be improved and blurring may be prevented in the perpendicular magnetic recording medium 50.

### Sixth Embodiment

In the following, a perpendicular magnetic recording medium 58 according to a sixth embodiment of the present invention is described. The perpendicular magnetic recording medium 58 of the present embodiment has a structure that is generally identical to that of the perpendicular magnetic recording medium 50 of the fifth embodiment; however, the perpendicular magnetic recording medium 58 of the present embodiment includes a second underlayer 21 between a first underlayer 14 and a recording layer 55. In other words, the perpendicular magnetic recording medium of the present embodiment has combined features of the second embodiment and the fifth embodiment.

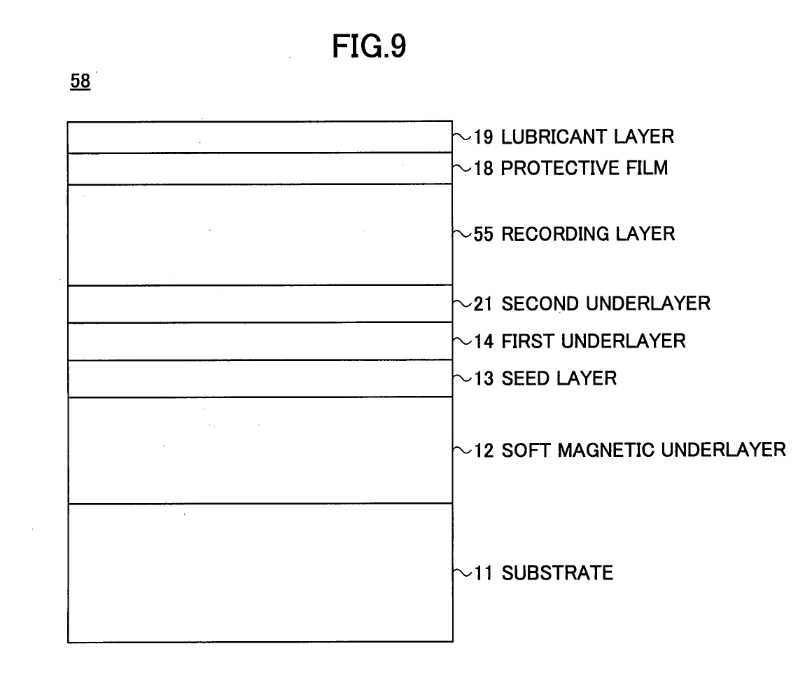

FIG. 9 is a cross-sectional diagram showing a configuration of the perpendicular magnetic recording medium 58 according to the sixth embodiment. In this drawing, components that are identical to those described in relation to the first through fifth embodiment are given the same references and their descriptions are omitted.

Referring to FIG. 9, the perpendicular magnetic recording medium 58 includes a substrate 11 on which a soft magnetic underlayer 12, a seed layer 13, a first underlayer 14, a second underlayer 21, a recording layer 55, a protective film 18, and a lubricant layer 19 are laminated in this order. It is noted that the recording layer 55 corresponds to a composition modulated film as is described in relation to the fifth embodiment.

By providing the second underlayer 21 in the perpendicular magnetic recording medium 58, the crystalline structure of the magnetic grains of the recording layer 55 may be further improved. That is, a combination of the advantageous effects of the second embodiment and the fifth embodiment described above may be realized in the perpendicular magnetic recording medium 58 of the present embodiment. In this way, the S/N ratio may be further improved in the perpendicular magnetic recording medium 58 of the present embodiment.

### Seventh Embodiment

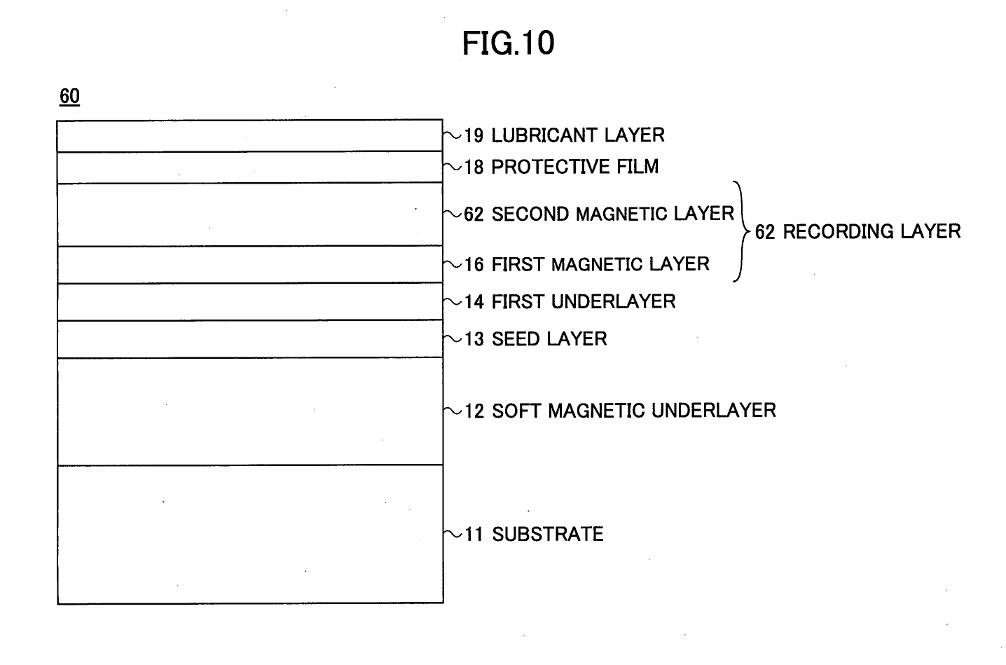

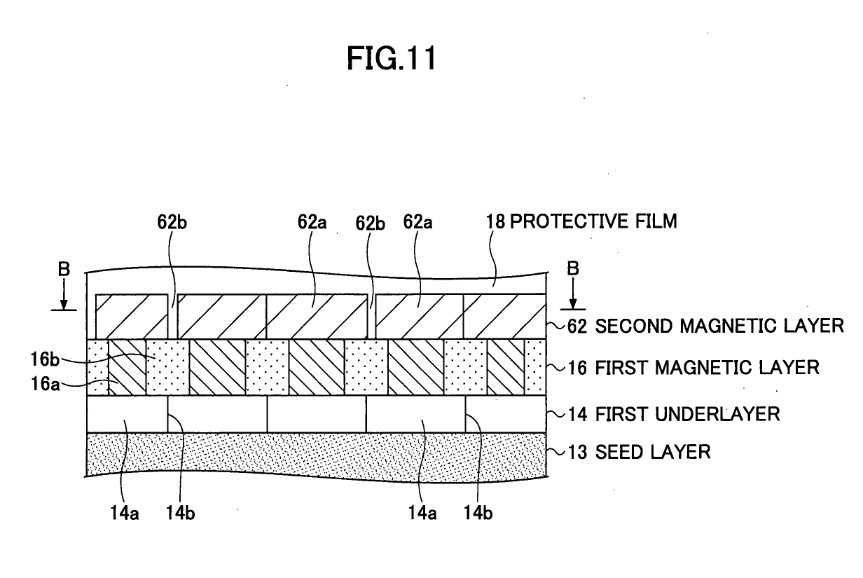

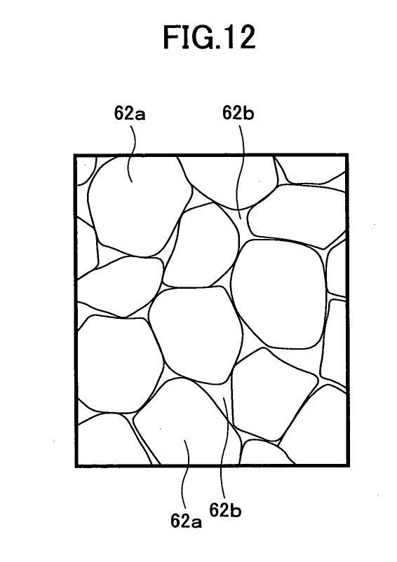

FIG. 10 is a cross-sectional diagram showing a configuration of a perpendicular magnetic recording medium according to a seventh embodiment of the present invention; FIG. 11 is a diagram showing a detailed structure of the perpendicular magnetic recording medium shown in FIG. 10; and FIG. 12 is a cross-sectional view of FIG. 11 cut across line B-B. It is noted that components illustrated in these drawings that corresponds to the components described in relation to the previous embodiments are assigned the same numerical references and their descriptions are omitted.

Referring to FIGS. 10-12, the perpendicular magnetic recording medium 60 of the seventh embodiment includes a substrate 11 on which a soft magnetic underlayer 12, a seed layer 13, a first underlayer 14, a recording layer 61, a protective film 18, and a lubricant layer 19 are laminated in this order. The recording layer 61 includes a first magnetic layer 16 and a second magnetic layer 62 that are laminated in this order from the first underlayer 14 side. It is noted that the perpendicular magnetic recording medium 60 has a similar configuration to that of the perpendicular magnetic recording medium 10 of the first embodiment other than the fact that the second magnetic layer 62 is made of metallic hard magnetic material. That is, materials and film thicknesses of other layers of the perpendicular magnetic recording medium 60 of the present embodiment may be selected from the materials and film thickness ranges for realizing the perpendicular magnetic recording medium 10 of the first embodiment.

The second magnetic layer 62 is made of hard magnetic material corresponding to one of Ni, Fe, Co, Ni alloy, Fe alloy, CoCr, CoPt, or CoCr alloy. Examples of the CoCr alloy include CoCrTa, CoCrPt, CoCrPt-M2. Herein, M2 may be selected from the group of elements B, Mo, Nb, Ta, W, Cu, and alloys thereof. The second magnetic layer 62 has easy magnetization axes that are substantially perpendicular to the substrate surface.

The saturation flux density of the second magnetic layer 62 is arranged to be higher than the saturation flux density of the first magnetic layer 16. It is noted that the playback output level of a magnetic head is substantially proportional to the sum of the product of the remnant flux density and the film thickness of the first magnetic layer 16 and the product of the remnant flux density and the film thickness of the second magnetic layer 62. By arranging the saturation flux density of the second magnetic layer 17 to be higher than the saturation flux density of the first magnetic layer 16, the remnant flux density of the second magnetic layer 17 may be higher than the remnant flux density of the first magnetic layer 16 compared to a case in which the first magnetic layer 16 and the second magnetic layer 17 are arranged to have the same saturation flux density. Accordingly, a desired playback output level may be achieved by providing the second magnetic layer 62 compared to the case of providing just the first magnetic layer 16 since the overall thickness of the recording layer 61 may be reduced. Therefore, the distance from a recording/playback element (not shown) of the magnetic head to the surface of the soft magnetic underlayer 12 may be reduced, and spacing loss occurring upon playback may be reduced to realize a higher output. At the same time, bleeding may be prevented upon recording. In one specific example, the saturation flux density of the first magnetic layer 16 may be 200-300 emu/cm³, and the saturation flux density of the second magnetic layer 62 may be 400-600 emu/cm³ so that the saturation flux density of the second magnetic layer 62 may be approximately two times that of the first magnetic layer 16 to realize substantial thickness reduction.

Also, it is noted that the hard magnetic material of the second magnetic layer 62 is preferably arranged to be the same type of hard magnetic material as that of the magnetic grains 16a of the first magnetic material. In this way, epitaxial growth of the magnetic grains 62a of the second magnetic layer 62 from the magnetic grains 16a of the first magnetic layer 16 may be facilitated, and the crystalline structure and the crystal orientation of the magnetic grains 62a of the second magnetic layer 62 may be improved. In the following, exemplary combinations of materials of the same type are described.

For example, in the case where the hard magnetic material of the magnetic grains 16a of the first magnetic layer 16 corresponds to Ni or an Ni alloy, the second magnetic layer 62 is preferably made of Ni or an Ni alloy. In the case where the hard magnetic material of the magnetic grains 16a of the first magnetic layer 16 corresponds to Fe or an Fe alloy, the second magnetic layer 62 is preferably made of Fe or an Fe alloy.

Further, in the case where the hard magnetic material of the magnetic grains 16a of the first magnetic layer 16 corresponds to a hard magnetic material having a hcp structure and including Co as a main component, the hard magnetic material of the second magnetic layer 62 preferably corresponds to a hard magnetic material having a hcp structure and including Co as a main component. It is noted that a hard magnetic material including Co as a main component refers to a hard magnetic material of which the Co content is at least 50 atomic %. In the case where the hard magnetic material of the magnetic grains 16a of the first magnetic layer 16 corresponds to CoCr, CoPt, or a CoCr alloy, the hard magnetic material of the second magnetic layer 62 preferably corresponds to CoCr, CoPt, or a CoCr alloy. More specifically, the hard magnetic material of the second magnetic layer 62 may correspond to CoCrTa, CoCrPt, or CoCrPt-M2, for example, as the CoCr alloy. Herein, M2 may be selected from the group of elements B, Mo, Nb, Ta, W, Cu, and alloys thereof.

As is shown in FIG. 11, the magnetic grains 62a of the second magnetic layer 62 are grown from the surfaces of the magnetic grains 16a of the first magnetic layer 16 to thereby cover the surfaces of the magnetic grains 16a. Since the magnetic grains 16a of the first magnetic layer 16 are evenly arranged and segregated from one another in parallel directions with respect to the substrate surface, the magnetic grains 62a of the second magnetic layer 62 may also be evenly arranged in parallel directions with respect to the substrate surface. Specifically, the size of the magnetic grains 62a of the second magnetic layer 62 may be arranged to be uniform. As a result, medium noise from the second magnetic layer 62 may be reduced, and in turn, the overall medium noise of the recording layer 61 may be reduced. It is particularly noted that in a preferred embodiment, the magnetic grains 62a of the second magnetic layer 62 are formed on the surfaces of the magnetic grains 16a of the first magnetic layer 16 on a one-to-one basis.

As is shown in FIGS. 11 and 12, in the second magnetic layer 62, a gap 62b is preferably formed at some of the interfaces between adjacent magnetic grains 62a. It is noted that the gap 62b may have the effect of reducing or cutting the magnetic interaction between the magnetic grains 62a, for example.

Also, it is noted that the arrangement of the magnetic grains 62a of the second magnetic layer 62 is determined by the arrangement of the magnetic grains 16a of the first magnetic layer 16. In a case where the second magnetic layer 62 is made of a CoCr alloy such as CoCrPt or CoCrPt-M2, the second magnetic layer 62 is formed on an appropriate underlayer such as a Ta film so that a center portion of a magnetic grain has hard magnetic properties while a nonmagnetic grain boundary is formed at the periphery thereof (i.e., the so-called Cr segregation grain boundary structure). However, in the seventh embodiment, since the second magnetic layer 62 is formed on the first magnetic layer 16, the magnetic grains 62a of the second magnetic layer 62 are arranged according to the arrangement of the magnetic grains 16a of the first magnetic layer 16, and thereby, the magnetic grains 62a may be separated from each other. Accordingly, the Cr segregation grain boundary structure does not necessarily have to be realized at the second magnetic layer 62. It is noted that when a CoCrPt material is used, a high content of Cr is added in order to facilitate the occurrence of Cr segregation. However, in the case or the second magnetic layer 62, the amount of Cr to be added may be reduced compared to the conventional amount of Cr. For example, in the case where the hard magnetic material of the second magnetic layer 62 corresponds to CoCrPt or CoCrPt-M2, the Cr content of the material is preferably within a range of 5-20 atomic %.

Also, it is noted that the second magnetic material 62 is preferably made of CoCrPt rather than CoCrPt-M2. Specifically, since the dopant element M2 corresponds to a nonmagnetic element, the saturation flux density of the second magnetic layer 62 may be higher when such dopant element M2 is not included, and in this way, the remnant flux density of the second magnetic layer 62 may be increased. In turn, the film thickness of the second magnetic layer 62 may be reduced and the film thickness of the first magnetic layer 16 may be reduced at the same time so that the overall film thickness of the recording layer 61 may be reduced. Consequently, the occurrence of spacing loss upon playback may be reduced further, and a high playback output may be realized. At the same time, bleeding upon recording may be prevented. Also, it is noted that the dopant element M2 may thwart the crystallization of CoCrPt in a case where the substrate temperature upon depositing the second magnetic layer 62 is set to room temperature, and thereby, improved crystalline structure of the second magnetic layer 62 may be achieved when the dopant element M2 is not doped in the material of the second magnetic layer 62. Accordingly, high playback output may be achieved in the perpendicular magnetic recording medium 60 from this aspect as well.

Also, in the case where the hard magnetic material of the second magnetic layer 62 corresponds to CoCrPt or CoCrPt-M2, the Pt content of the material is set to a point at which the perpendicular coercive force may be adequately low, preferably within a range of 5-10 atomic %.

The second magnetic layer 62 is preferably arranged to have a film thickness within a range of 6-10 nm, and more preferably within a range of 6-8 nm. The first magnetic layer 16 is preferably arranged to have a film thickness within a range of 1-4 nm, and more preferably within a range of 2-3 nm.

Further, it is noted that the film thickness of the second magnetic layer 62 is preferably arranged to be equal to or less than the film thickness of the first magnetic layer 16. In this way, reduction of the overall film thickness of the recording layer 61, formation of the first magnetic layer 16 into a granular structure, and high playback output may be realized at the same time. Also, in a preferred embodiment, the ratio of the film thickness t1 of the first magnetic layer 16 to the film thickness t2 of the second magnetic layer 62 (t1/t2) is preferably within a range of 1-2 in order to realize a good S/N ratio. It is noted that in a case where the ratio t1/t2 is less than 1, the S/N ratio may be degraded at a high frequency, and when the ratio t1/t2 is greater than 2, the S/N ratio may be degraded at a low frequency. Also, the total sum of the film thickness of the first magnetic layer 16 and the film thickness of the second magnetic layer 62 is preferably no more than 20 nm.

It is noted that the second magnetic layer 62 is not limited to a single layer structure; that is, the second magnetic layer 62 may also be a laminated structure made up of plural layers, for example. In this case, the layers making up the laminated structure may be made of the same combination of elements realizing the same type of hard magnetic material with differing element composition ratios, or the layers may be made of different combinations of elements. That is, the layers may be selected from any of the possible hard magnetic materials of the second magnetic layer 62 described above.

According to the present embodiment, the perpendicular magnetic recording medium 60 includes a recording layer 61 realized by depositing the second magnetic layer 62 made of metallic hard magnetic material on the first magnetic layer 16 having a granular structure. As is described above in relation to the first embodiment, the magnetic grains 16a of the first magnetic layer 16 may be evenly arranged. Since the magnetic grains 62a of the second magnetic layer 62 are formed on the surfaces of the magnetic grains 16a of the first magnetic layer 16, the even arrangement of the magnetic grains 16a of the first magnetic layer 16 may be passed on to the second magnetic grain 62. In this way, the magnetic grains 62a of the second magnetic layer 62 may be evenly arranged as well. As a result, medium noise may be reduced. Also, since the saturation flux density of the second magnetic layer 62 is arranged to be higher than the saturation flux density of the first magnetic layer 16 to thereby reduce the overall film thickness of the recording layer 61, and since the saturation flux density of the layer closer to the magnetic head is higher, high playback output may be achieved in the perpendicular magnetic recording medium 60. Accordingly, a good S/N ratio as well as a high playback output may be realized in the perpendicular magnetic recording medium 60.

In the following, a method for manufacturing the perpendicular magnetic recording medium 60 of the seventh embodiment is described with reference to FIG. 10.

It is noted that the process steps from cleaning the substrate to forming the first magnetic layer 16 are performed in a manner identical to the corresponding process steps of the method for manufacturing the perpendicular magnetic recording medium 10 of the first embodiment as is described above.

The second magnetic layer 62 is formed through DC magnetron sputtering using a sputtering target made of the hard magnetic material of the second magnetic layer 62 in an inactive gas atmosphere such as an Ar gas atmosphere (e.g, set to an atmospheric pressure of 0.4 Pa).

Then, the protective film 18 and the lubricant film 19 may be formed in a manner similar to the process steps of the method for manufacturing the perpendicular magnetic recording medium 10 of the first embodiment. In this way, the perpendicular magnetic recording medium 60 of the seventh embodiment may be manufactured.

It is noted that in the present manufacturing method, a heating process is not performed on the substrate during the process of forming the soft magnetic underlayer 12 through forming the second magnetic layer 62. In this way, the crystallization of the non-crystalline material of the soft magnetic underlayer 12 may be prevented, and the granular structure of the first magnetic layer 16 may be accurately formed. Accordingly, the substrate temperature is approximately at room temperature at the time the second magnetic layer 62 is formed. In this case, if the hard magnetic material of the second magnetic layer 62 corresponds to a Co Cr alloy, for example, the Cr segregation structure may hardly be realized in the magnetic grains 62a of the second magnetic layer 62. Specifically, a substantially uniform structure is formed within the magnetic grains 62a of the second magnetic layer 62 by the composition of the hard magnetic material of the second magnetic layer 62. In this case, designing of the hard magnetic material of the second magnetic layer 62 may be facilitated. Also, a chamber for heating the substrate may not be necessary so that equipment cost and manufacturing cost may be reduced, and the accommodating area of the sputtering apparatus may be reduced as well.

Also, as is described above, the magnetic grains 62a of the second magnetic layer 62 may be separated from each other in accordance with the arrangement of the first magnetic layer 16, and thereby, medium noise may be reduced and the S/N ratio may be improved in the second magnetic layer 62.

### Eighth Embodiment

A perpendicular magnetic recording medium according to an eighth embodiment of the present invention is substantially identical to the perpendicular magnetic recording medium according to the second embodiment other than the fact that it includes a second magnetic layer identical to that of the seventh embodiment.

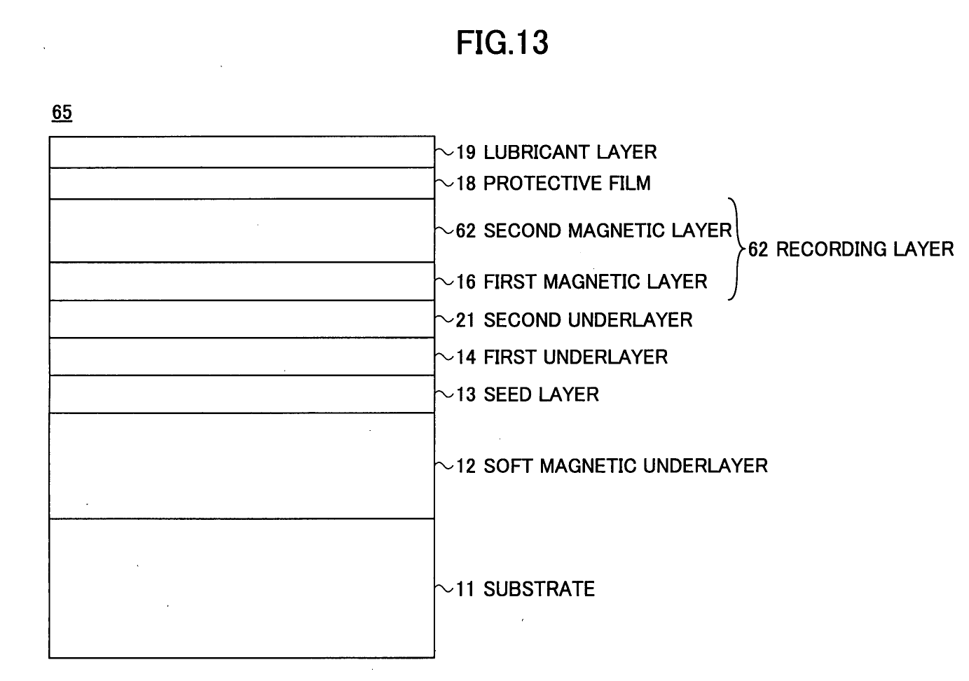

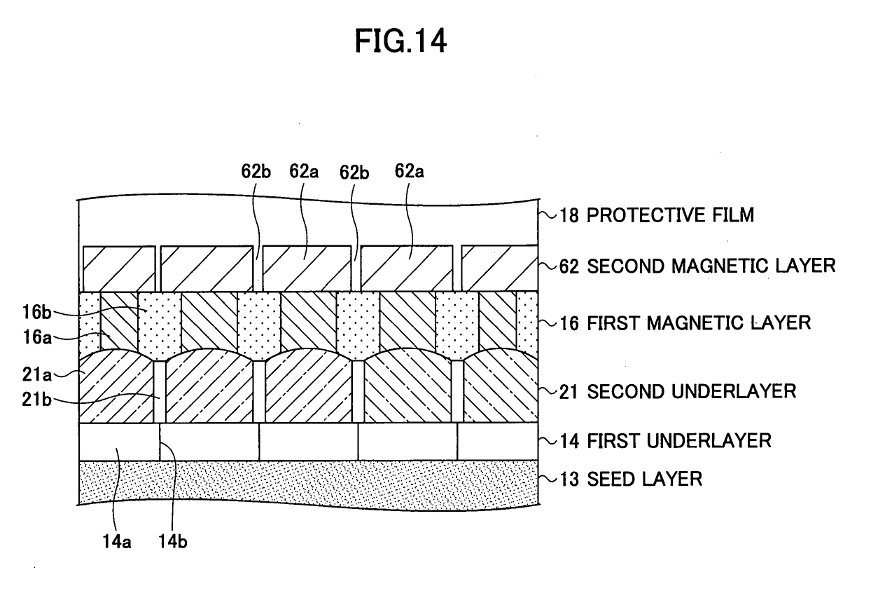

FIG. 13 is a cross-sectional diagram showing a configuration of a perpendicular magnetic recording medium according to an eighth embodiment of the present invention, and FIG. 14 is a diagram showing a detailed structure of the perpendicular magnetic recording medium shown in FIG. 13. It is noted that components illustrated in these drawings that are identical to those described in relation to the previously described embodiments are give the same numerical references and their descriptions are omitted.

Referring to FIGS. 13 and 14, the perpendicular magnetic recording medium 65 of the present embodiment includes a substrate 11 on which a soft magnetic underlayer 12, a seed layer 13, a first underlayer 14, a second underlayer 21, a recording layer 61, a protective film 18, and a lubricant layer 19 are laminated in this order. The recording layer 61 includes a first magnetic layer 16 and a second magnetic layer 62 that are laminated in this order from the second underlayer 21 side. It is noted that the perpendicular magnetic recording medium 65 has a similar configuration to that of the perpendicular magnetic recording medium 20 of the second embodiment other than the fact that the second magnetic layer 62 is made of metallic hard magnetic material. That is, materials and film thicknesses of other layers of the perpendicular magnetic recording medium 65 of the present embodiment may be selected from the materials and film thickness ranges for realizing the perpendicular magnetic recording medium 20 of the second embodiment.

As is described above in relation to FIGS. 4 and 5 that illustrate the second embodiment, the second under layer 21 includes plural crystal grains 21a that are made of Ru or Ru-M1 alloy (M1 corresponding to at least one of the elements CO, Cr, Fe, Ni, and Mn) having a hcp structure and including Ru as a main component, which crystal grains 21a are surrounded by a void portion 21b that separates the crystal grains 21a from each other. The crystal grain 21a may adequately separate the magnetic grains 16a of the first magnetic layer 16 from each other. Also, by providing the second underlayer 21, the crystalline structure of the magnetic grains 16a of the first magnetic layer 16 may be improved. In turn, the spacing between the magnetic grains 62a of the second magnetic layer 62 may be evened out as is shown in FIG. 14. Accordingly, the medium noise of the perpendicular magnetic recording medium 65 may be reduced and its S/N ratio may be improved. Also, the gaps 62b between the magnetic grains 62a of the second magnetic layer 62 may be evenly formed. In this way, the range or variations in the amount of interaction between the magnetic grains 62a of the second magnetic layer 62 may be reduced so that medium noise may be reduced and the S/N ratio may be improved in the perpendicular magnetic recording medium 65.

It is noted that the method for manufacturing the perpendicular magnetic recording medium 65 according to the eighth embodiment involves forming the second underlayer 21 by performing the corresponding process step of the method for manufacturing the perpendicular magnetic recording medium 20 of the second embodiment, and forming the other layers by performing the corresponding process steps of the method for manufacturing the perpendicular magnetic recording medium 60 according to the seventh embodiment.

### Ninth Embodiment

A perpendicular magnetic recording medium 70 according to a ninth embodiment of the present invention includes a recording layer 71 that is realized by arranging the second magnetic layer 62 of the perpendicular magnetic recording medium 60 according to the seventh embodiment on the n^{th} magnetic layer of the recording layer 35 of the perpendicular magnetic recording medium 30 according to the third embodiment.

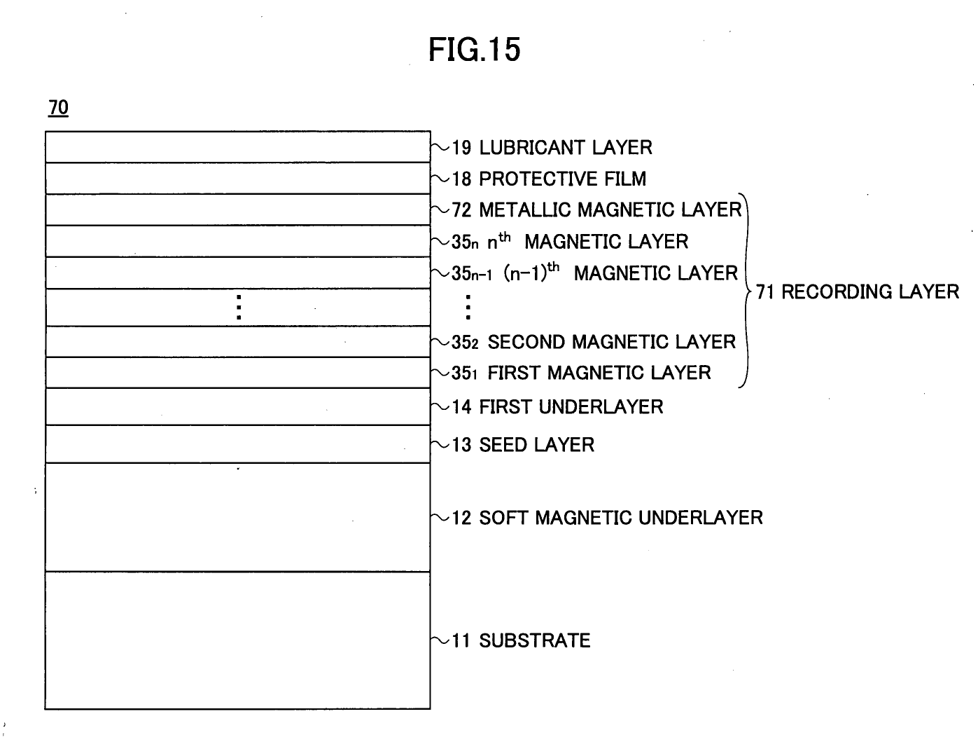

FIG. 15 is a cross-sectional diagram showing a configuration of a perpendicular magnetic recording medium according to a ninth embodiment of the present invention. It is noted that components shown in this drawing that are identical to those described in relation to the previous embodiments are given the same numerical references and their descriptions are omitted.

Referring to FIG. 15, the perpendicular magnetic recording medium 70 of the present embodiment includes a substrate 11 on which a soft magnetic underlayer 12, a seed layer 13, a first underlayer 14, a recording layer 71, a protective film 18, and a lubricant layer 19 are laminated in this order. The recording layer 71 includes a first magnetic layer 35₁, a second magnetic layer 35₂, . . . , a (n−1)^{th} magnetic layer 35₍ₙ₋₁₎, a n^{th} magnetic layer 35ₙ, and a metallic magnetic layer 72 that are laminated in this order from the first underlayer 14 side. Herein, n corresponds to an integer greater than or equal to 3. It is noted that the perpendicular magnetic recording medium 70 has a similar configuration to that of the perpendicular magnetic recording medium 30 of the third embodiment other than the fact that it includes the metallic magnetic layer 72 made of metallic hard magnetic material that is arranged on the n^{th} magnetic layer 35ₙ. That is, materials and film thicknesses of other layers of the perpendicular magnetic recording medium 70 of the present embodiment may be selected from the materials and film thickness ranges for realizing the perpendicular magnetic recording medium 30 of the third embodiment.

The material and film thickness of the metallic magnetic layer 72 may be selected from the possible materials and film thickness range described above for realizing the second magnetic layer 62 of the perpendicular magnetic recording medium 60 of the seventh embodiment as is illustrated in FIG. 10. Also, as is described above in relation to the third embodiment, the first magnetic layer 35₁ through the n^{th} magnetic layer 35ₙ are each arranged into granular structures. The first magnetic layer 35₁ through the (n−1)^{th} magnetic layer 35ₙ₋₁ are arranged such that the atomic concentrations of their corresponding non-soluble phases are set higher than the second magnetic layer 35₂ through the n^{th} magnetic layer 35ₙ, respectively, that are deposited directly on top of the above magnetic layers. Also, since the metallic magnetic layer 72 is formed on the n^{th} magnetic layer 35ₙ, the atomic concentration of the magnetic grains may be increased and the playback output level may be increased.

Also, since the magnetic grains of the first magnetic layer 35₁ through the (n-1)^{th} magnetic layer 35ₙ₋₁ are arranged to be separated from each other, the evenness in the arrangement of the magnetic grains of the metallic magnetic layer may be improved. In this way, the medium noise may be reduced and the S/N ratio may be improved in the perpendicular magnetic recording medium 70.

It is noted that a method for manufacturing the perpendicular magnetic recording medium 70 according to the ninth embodiment is substantially identical to the method for manufacturing the perpendicular magnetic recording medium 65 of the eighth embodiment, and descriptions thereof are omitted.

### Tenth Embodiment

A perpendicular magnetic recording medium 75 according to a tenth embodiment of the present invention is realized by arranging the second magnetic layer 62 of the perpendicular magnetic recording medium 60 according to the seventh embodiment on the n^{th} magnetic layer 35ₙ of the perpendicular magnetic recording medium 40 according to the fourth embodiment.

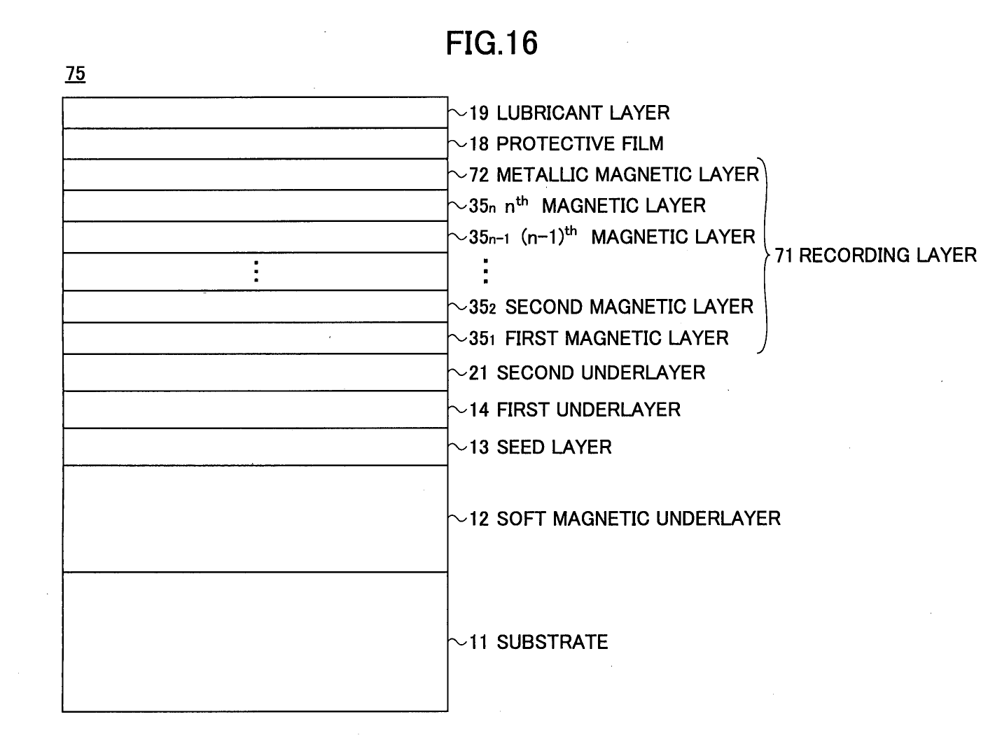

FIG. 16 is a cross-sectional diagram showing a configuration of a perpendicular magnetic recording medium according to a tenth embodiment of the present invention. Referring to FIG. 16, the perpendicular magnetic recording medium 75 of the present embodiment includes a substrate 11 on which a soft magnetic underlayer 12, a seed layer 13, a first underlayer 14, a second underlayer 21, a recording layer 71, a protective film 18, and a lubricant layer 19 are laminated in this order. The recording layer 71 includes a first magnetic layer 35₁, a second magnetic layer 35₂, . . . , a (n−1)^{th} magnetic layer 35₍ₙ₋₁₎, a n^{th} magnetic layer 35ₙ, and a metallic magnetic layer 72 that are laminated in this order from the first underlayer 14 side. Herein, n corresponds to an integer greater than or equal to 3. It is noted that the perpendicular magnetic recording medium 75 has a similar configuration to that of the perpendicular magnetic recording medium 70 of the ninth embodiment other than the fact that it includes the second underlayer 21.

The perpendicular magnetic recording medium 75 may realize advantages similar to those realized by the perpendicular magnetic recording medium 70 according to the ninth embodiment. Further, by providing the second underlayer 21, the crystalline structure of the magnetic grains of the magnetic layers 35₁ through 35ₙ may be improved, and the crystalline structure of the metallic magnetic layer 72 may be improved as well. In this way, the playback output level may be increased.

Also, by providing the second underlayer 21, the magnetic grains of the first magnetic layer 35₁ may be adequately separated. In turn, such an arrangement of the magnetic grains may be passed on to the second magnetic layer 35₂ up to the n^{th} magnetic layer 35ₙ. In this way, the S/N ratio of the perpendicular magnetic recording medium 75 may be improved.

It is noted that a method for manufacturing the perpendicular magnetic recording medium 75 according to the tenth embodiment is substantially identical to the method for manufacturing the perpendicular magnetic recording medium 65 of the eighth embodiment, and descriptions thereof are omitted.

### Eleventh Embodiment

A perpendicular magnetic recording medium according to an eleventh embodiment of the present invention is realized by arranging the second magnetic layer 62 of the perpendicular magnetic recording medium 60 according to the seventh embodiment on the recording layer 55 of the perpendicular magnetic recording medium 50 according to the fifth embodiment.

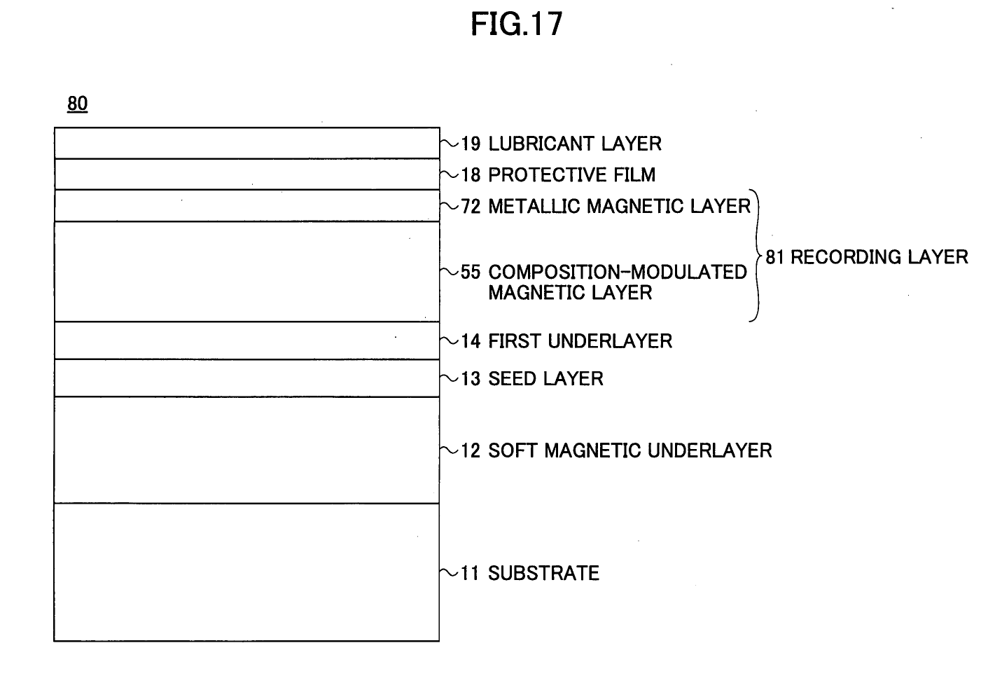

FIG. 17 is a cross-sectional diagram showing a configuration of a perpendicular magnetic recording medium according to an eleventh embodiment of the present invention. It is noted that components shown in this drawing that are identical to those described in relation to the previous embodiments are given the same numerical references and their descriptions are omitted.

Referring to FIG. 17, the perpendicular magnetic recording medium 80 of the present embodiment includes a substrate 11 on which a soft magnetic underlayer 12, a seed layer 13, a first underlayer 14, a recording layer 81, a protective film 18, and a lubricant layer 19 are laminated in this order. The recording layer 81 includes a composition modulated film in which the atomic concentration of the non-soluble phase within this recording layer 55 gradually decreases in the direction from the first underlayer 14 to the protective film 18, and a metallic magnetic layer 72 that is laminated thereon. It is noted that the perpendicular magnetic recording medium 80 has a similar configuration to that of the perpendicular magnetic recording medium 50 of the fifth embodiment as is illustrated in FIG. 5 other than the fact that it includes the metallic magnetic layer 72 made of metallic hard magnetic material that is arranged on the composition modulated film 55. That is, materials and film thicknesses of other layers of the perpendicular magnetic recording medium 80 of the present embodiment may be selected from the materials and film thickness ranges for realizing the perpendicular magnetic recording medium 50 of the fifth embodiment.

The material and film thickness of the metallic magnetic layer 72 may be selected from the possible materials and film thickness range described above for realizing the second magnetic layer 62 of the perpendicular magnetic recording medium 60 of the seventh embodiment as is illustrated in FIG. 10. Also, the atomic concentration of the non-soluble phase of the composition modulated magnetic layer 55 at the interface with the first underlayer 14 is arranged to be relatively high, and the atomic concentration of the non-soluble phase is arranged to gradually decrease upon nearing the protective film 18. By realizing such an arrangement, the magnetic grains (not shown) of the composition modulated magnetic layer 55 may be separated from each other at the interface with the first underlayer 14. It is noted that the respective diameters of the magnetic grains of the composition modulated magnetic layer 55 are arranged to gradually increase; however, since the base portions of the magnetic grains are separated from each other bonding of the magnetic grains may be prevented over the film thickness direction range of the composition modulated magnetic layer 55. Also, since the metallic magnetic layer 72 is formed on the composition modulated magnetic layer 55, the spacing between the magnetic grains of the metallic magnetic layer 72 may be evened out, and as a result, the medium noise of the perpendicular magnetic recording medium 80 may be reduced. In turn, the S/N ratio of the perpendicular magnetic recording medium 80 may be improved. In another aspect, the film thickness of the recording layer 81 of the perpendicular magnetic recording medium 80 may be reduced while maintaining the playback output level.

It is noted that a method for manufacturing the perpendicular magnetic recording medium 80 according to the evleventh embodiment is substantially identical to the method for manufacturing the perpendicular magnetic recording medium 65 of the eighth embodiment, and descriptions thereof are omitted.

### Twelfth Embodiment

A perpendicular magnetic recording medium according to a twelfth embodiment of the present invention is realized by arranging the second magnetic layer 62 of the perpendicular magnetic recording medium 60 according to the seventh embodiment on the recording layer 55 of the perpendicular magnetic recording medium 60 according to the sixth embodiment.

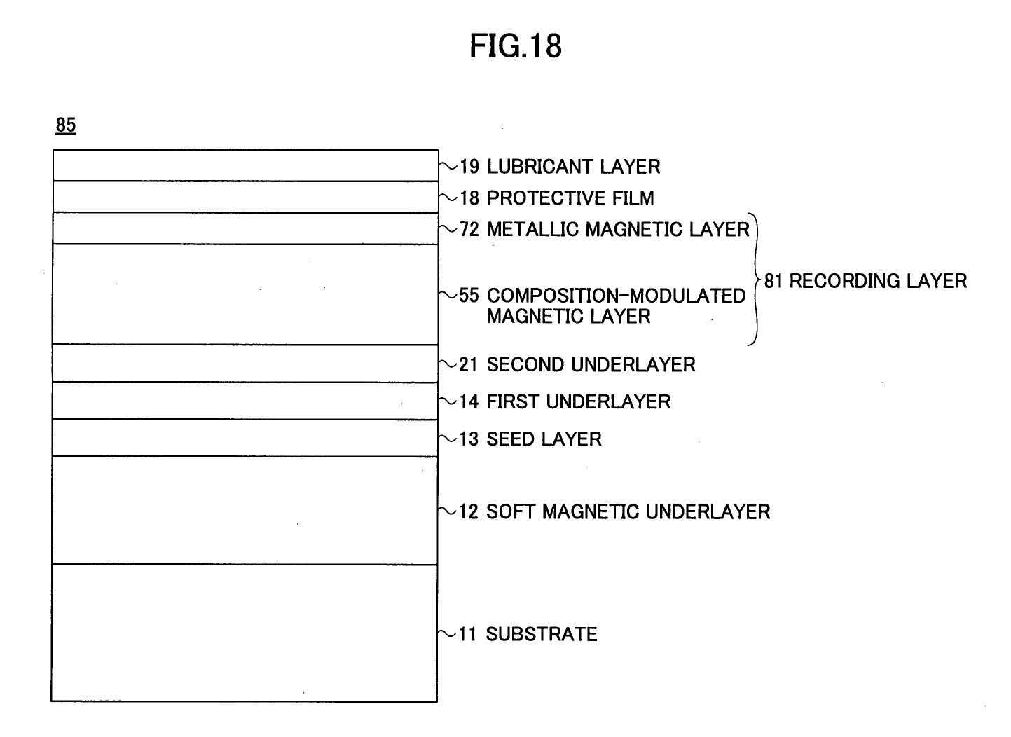

FIG. 18 is a cross-sectional diagram showing a configuration of a perpendicular magnetic recording medium according to the twelfth embodiment of the present invention. It is noted that components shown in this drawing that are identical to those described in relation to the previous embodiments are given the same numerical references and their descriptions are omitted.

Referring to FIG. 18, the perpendicular magnetic recording medium 85 of the present embodiment includes a substrate 11 on which a soft magnetic underlayer 12, a seed layer 13, a first underlayer 14, a second underlayer 21, a recording layer 81, a protective film 18, and a lubricant layer 19 are laminated in this order. The recording layer 81 is made up of the composition modulated film 55 having a configuration identical to that described in relation to the eleventh embodiment, and a metallic magnetic layer 72 that is laminated thereon. It is noted that the perpendicular magnetic recording medium 85 has a similar configuration to that of the perpendicular magnetic recording medium 80 of the tenth embodiment as is illustrated in FIG. 17 other than the fact that it includes the second underlayer 21. That is, materials and film thicknesses of other layers of the perpendicular magnetic recording medium 85 of the present embodiment may be selected from the materials and film thickness ranges for realizing the perpendicular magnetic recording medium 80 of the eleventh embodiment.

The perpendicular magnetic recording medium 85 may realize advantages similar to those realized by the perpendicular magnetic recording medium 80 according to the eleventh embodiment. Further, by providing the second underlayer 21, the crystalline structure of the magnetic grains of the composition modulated magnetic layer 55 of the recording layer 81 may be improved, and the crystalline structure of the metallic magnetic layer 72 may be improved as well. In this way, the playback output level may be increased.

Also, by providing the second underlayer 21, the magnetic grains of the composition modulated magnetic layer 55 may be adequately separated at the interface with the second underlayer 21. Such an arrangement of the magnetic grains may be passed on to the metallic magnetic layer 72 so that a more even magnetic grain arrangement may be realized. In this way, the S/N ratio of the perpendicular magnetic recording medium 85 may be improved.

It is noted that a method for manufacturing the perpendicular magnetic recording medium 85 according to the evleventh embodiment is substantially identical to the method for manufacturing the perpendicular magnetic recording medium 65 of the eighth embodiment, and descriptions thereof are omitted.

### Specific Embodiments

In the following magnetic disks according to embodiments 1-4 as specific embodiments of the perpendicular magnetic recording medium of the seventh embodiment of the present invention are described. It is noted that different types of hard magnetic material are used for the second magnetic layer in the magnetic disks of embodiments 1-4. Also, the magnetic disks according to the embodiments 2-4 are arranged to have first magnetic layers with differing film thicknesses.

A configuration that is common for all the magnetic disks of the embodiments 1-4 is described below.

Substrate: glass substrate

Soft magnetic underlayer: CoZrNb film (200 nm)

Seed layer: Ta film (3 nm)

First underlayer: Ru film (13.2 nm)

First magnetic layer: (Co₇₀Cr₉Pt₂₁)₈₇—(SiO₂)₁₃ film

Protective film: carbon film (3 nm)

Lubricant film: perfluoropolyester lubricant layer (1 nm)

As for the second magnetic layer, a Co₁₆Cr₂₀Pt₁₅B₄ film (7.5 nm) is used in embodiment 1; a Co₇₅Cr₂₀Pt₅ film (6.0 nm) is used in embodiment 2; a Co₇₀Cr₂₀Pt₁₀ film (6.0 nm) is used in embodiment 3; and a laminated layer including a Co₇₅Cr₂₀Pt₅ film (2.5 nm) and Co₇₀Cr₂₀Pt₁₀ film (3.0 nm) that are arranged in this order is used in embodiment 4.

After the glass substrate is cleaned, a DC magnetron sputtering apparatus is used to successively form the CoZrNb film and the Ta film in an Ar gas atmosphere of 0.399 Pa (3 mTorr). Then, using the DC magnetron sputtering apparatus, the Ru film is formed in an Ar gas atmosphere of 5.32 Pa at a deposition speed of 0.55 nm/sec. Then, using a CRF sputtering apparatus, the CoCrPt—SiO₂ film in an Ar gas atmosphere of 2.66 Pa. Then, the DC magnetron sputtering apparatus is used once more to form the second magnetic layer in an Ar gas atmosphere of 0.399 Pa (3 mTorr). It is noted that a heating process is not performed on the glass substrate during the above-described film deposition process. Then, the carbon film is deposited after which the lubricant film is applied through immersion and protrusions on the surface of the magnetic disk are removed by a polishing tape.

In an experiment, the average playback outputs with respect to a linear recording density of 124 kBPI realized by the magnetic disks of embodiments 1-4 manufactured in the above-described manner was measured using a perpendicular recording compound head and a commercial electromagnetic conversion measuring apparatus.

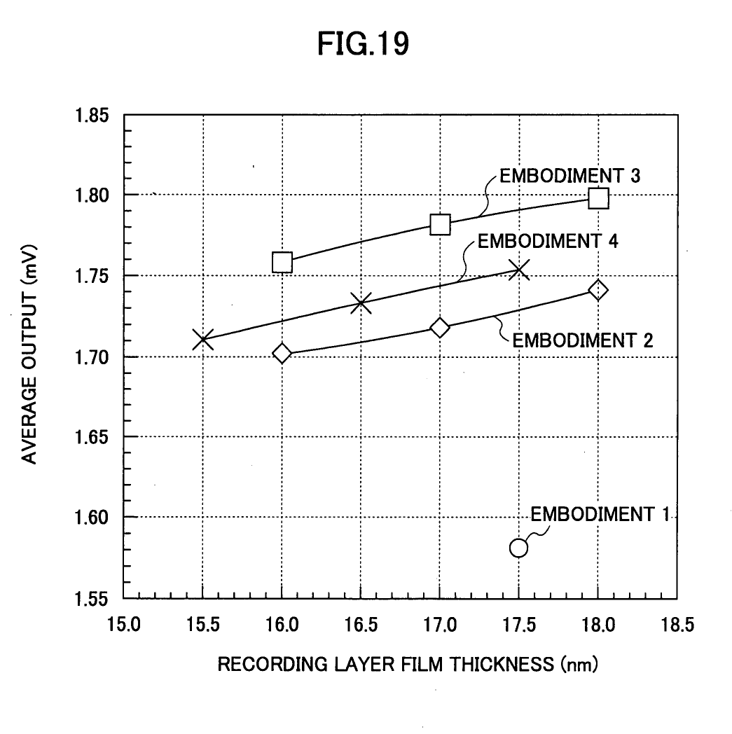

FIG. 19 is a graph indicating the relationship between the average playback output and the recording layer film thickness in the magnetic disks of embodiments 1-4.

As can be appreciated from FIG. 19, embodiments 2-4 realize higher playback outputs compared to embodiment 1. This is because even though the recording layer film thicknesses of embodiments 2-4 may be thinner than that of embodiment 1, the Co content of the second magnetic layers of embodiments 2-4 is higher than that of embodiment 1. Therefore, the saturation flux densities Bs of the second magnetic layers of embodiments 2-4 may be higher and the remnant flux densities of the second magnetic layers of embodiments 2-4 may be higher compared to embodiment 1. As can be appreciated, preferably, no dopant element is added to the CoCrPt material of the second magnetic layer in order to increase the playback output level for a low recording density. It is believed that such a dopant added to the material of the second magnetic layer tends to degrade the crystalline structure of the magnetic grains of the second magnetic layer.

Also, in comparing embodiments 2 and 3, it can be appreciated that embodiment 3 realizes a higher average playback output compared to embodiment 2. As is described above, the Pt content of the first magnetic layer in both embodiments 2 and 3 is 21 atomic %. As for the second magnetic layer, the Pt content is 5 atomic % in embodiment 2, and the Pt content is 10 atomic % in embodiment 3. It is noted that the Pt content affects the lattice constant; that is, the lattice constant increases as the Pt content increases. Therefore, embodiment 3 may achieve better lattice consistency in the second magnetic layer at the interface with the first magnetic layer compared to embodiment 2. Accordingly, the perpendicular orientation realized in embodiment 3 may be superior to that realized in embodiment 2 which in turn is believed to be a factor realizing a higher average playback output in embodiment 3. As can be appreciated from the above descriptions, in a case where the first magnetic layer and the second magnetic layer are made of CoCrPt, the Pt content of the second magnetic layer is preferably arranged to be close to the Pt content of the first magnetic layer. Also, it is noted that based on experiments conducted by the present inventor, the Pt content of the magnetic grains of the first magnetic layer is preferably 21 atomic %.

### Thirteenth Embodiment

In the following, a magnetic storage device 90 according to a thirteenth embodiment of the present invention that implements at least one of the perpendicular magnetic recording media according to the first through twelfth embodiments of the present invention is described.

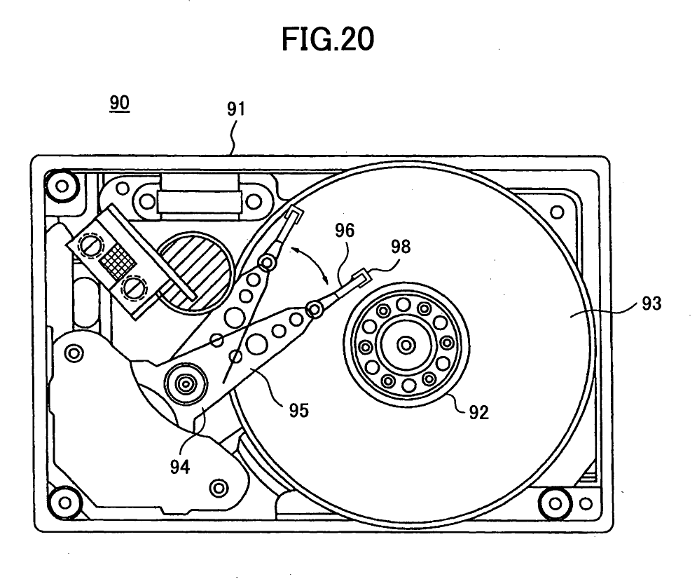

FIG. 20 is a diagram showing a configuration of the magnetic storage device 90 according to the thirteenth embodiment of the present invention.

Referring to FIG. 20, the magnetic storage device 90 includes a housing 91 inside which a hub 92 that is driven by a spindle (not shown), a perpendicular magnetic recording medium 93 that is stationed to and rotated by the hub 92, an actuator unit 94, an arm 95 and a suspension 96 that are attached to the actuator unit 94 and arranged to move in a radial direction of the perpendicular magnetic recording medium 93, and a magnetic head 98 that is supported by the suspension 96 are provided.

The magnetic head 98 may be made of a single pole recording head and a reproducing head including a GMR element (Giant Magneto Resistive), for example.

The single pole recording head may include a main magnetic pole made of soft magnetic material for applying a recording magnetic field to the perpendicular magnetic recording medium 93, a return yoke magnetically connected to the main magnetic pole, and a recording coil for guiding the recording magnetic field to the main magnetic pole and the return yoke, for example. The single pole recording head is arranged to apply a recording magnetic field from the main magnetic pole to the perpendicular magnetic recording medium 93 in a perpendicular direction to induce magnetization of the perpendicular magnetic recording medium 93 in the perpendicular direction.

The recording head may include a GMR element that is capable of acquiring information recorded on a recording layer of the perpendicular magnetic recording medium 93 by sensing a change in resistance to determine a magnetic field direction in which magnetization of the perpendicular magnetic recording medium 93 leaks. It is noted that a TMR (Tunnel Junction Magneto Resistive) element, for example, may be used in place of the GMR element.

The perpendicular magnetic recording medium 93 may correspond to one of the perpendicular magnetic recording media according to the first through twelfth embodiments of the present invention. As is described above, the medium noise is reduced in the perpendicular magnetic recording medium 93, and thereby the magnetic storage device 90 of the present invention may be capable of realizing high density recording.

It is noted that the structure of the magnetic storage device 90 according to the present embodiment is not limited to that illustrated in FIG. 20. Also, it is noted that the magnetic head 98 is not limited to that described above, and for example, a conventional magnetic head may be used as well. Also, the perpendicular magnetic recording medium 93 is not limited to a magnetic disk, and may correspond to other forms of media such as a magnetic tape.

According to the present embodiment, the magnetic storage device 90 may realize high density recording by using the perpendicular magnetic recording medium 63 with reduced medium noise.

Although the invention is shown and described with respect to certain preferred embodiments, the present invention is not limited to these embodiments, and variations and modifications may be made without departing from the scope of the present invention.

The present application is based on and claims the benefit of the earlier filing date of Japanese Patent Application No. 2005-099885 filed on Mar. 30, 2005, and Japanese Patent Application No. 2006-049313 filed on Feb. 24, 2006, the entire contents of which are hereby incorporated by reference.

What is claimed is:

1. A perpendicular magnetic recording medium, comprising:
a substrate;
a soft magnetic underlayer that is formed on the substrate;
a seed layer made of a non-crystalline material, which seed layer is formed on the soft magnetic underlayer;
a first underlayer made of Ru or an Ru alloy including Ru as a main component, which first underlayer is formed on the seed layer; and
a recording layer including a first magnetic layer and a second magnetic layer that is laminated on the first magnetic layer, which recording layer is formed on the first underlayer; wherein
the first underlayer includes a polycrystalline film that is formed by a plurality of first crystal grains that are bonded to each other via a crystal boundary portion;
the first magnetic layer includes a plurality of first magnetic grains having easy magnetization axes in a substantially perpendicular direction with respect to the substrate surface, and a first nonmagnetic non-soluble phase segregating the first magnetic grains from each other, which first non-soluble phase is provided at a first atomic concentration;
the second magnetic layer includes a plurality of second magnetic grains having easy magnetization axes in a substantially perpendicular direction with respect to the substrate surface, and a second nonmagnetic non-soluble phase segregating the second magnetic grains from each other, which second non-soluble phase is provided at a second atomic concentration; and
the first atomic concentration of the first non-soluble phase in the first magnetic layer is arranged to be higher than the second atomic concentration of the second non-soluble phase in the second magnetic layer.

2. The perpendicular magnetic recording medium as claimed in claim 1, wherein
the second magnetic grains of the second magnetic layer are arranged on the surfaces of the first magnetic grains of the first magnetic layer on a one-to-one basis.

3. The perpendicular magnetic recording medium as claimed in claim 1, further comprising:
a second underlayer made of Ru or an Ru alloy including Ru as a main component, which second underlayer is provided between the first underlayer and the recording layer; wherein
the second underlayer includes a plurality of second crystal grains that are grown in a perpendicular direction with respect to the substrate surface, and a void portion segregating the second crystal grains.

4. The perpendicular magnetic recording medium as claimed in claim 1, wherein
the Ru alloy has a hexagonal close packed structure and includes at least one of Co, Cr, Fe, Ni, and Mn.

5. The perpendicular magnetic recording medium as claimed in claim 1, wherein
the first atomic concentration of the first non-soluble phase in the first magnetic layer is arranged to be within a range of 10˜20 atomic %.

6. The perpendicular magnetic recording medium as claimed in claim 1, wherein
the second atomic concentration of the second non-soluble phase in the second magnetic layer is arranged to be within a range of 5˜15 atomic %.

7. The perpendicular magnetic recording medium as claimed in claim 1, wherein
the first magnetic layer is arranged to be thinner than the second magnetic layer.

8. The perpendicular magnetic recording medium as claimed in claim 1, wherein
the seed layer is made of at least one of elements Ta, Ti, C, Mo, W, Re, Os, Hf, Mg, and Pt, non-crystalline nonmagnetic alloys of said elements, and non-crystalline nonmagnetic NiP.

9. The perpendicular magnetic recording medium as claimed in claim 8, wherein
the seed layer corresponds to a single layer film having a film thickness within a range of 1.0˜10 nm.

10. The perpendicular magnetic recording medium as claimed in claim 1, wherein
the first magnetic grains and the second magnetic grains correspond to at least one of Ni, Fe, Co, a Ni alloy, a Fe alloy, and a Co alloy, said Co alloy including CoCr, CoPt, CoCrTa, CoCrPt, and an alloy made of CoCrPt and at least one of elements B, Mo, Nb, Ta, W, Cu, and alloys of said elements.

11. The perpendicular magnetic recording medium as claimed in claim 1, wherein
the first non-soluble phase and the second non-soluble phase corresponds to a compound that is made of one of Si, Al, Ta, Zr, Y, and Mg, and at least one of O, C, and N.

12. The perpendicular magnetic recording medium as claimed in claim 1, wherein
the first non-soluble phase and the second non-soluble phase include SiO₂;
an atomic concentration of SiO₂ in the first magnetic layer is set within a range of 10˜20 atomic %; and
an atomic concentration of SiO₂ in the second magnetic layer is set within a range of 5˜15 atomic %.

13. A perpendicular magnetic recording medium, comprising:
a substrate;
a soft magnetic underlayer that is formed on the substrate;
a seed layer made of a non-crystalline material, which seed layer is formed on the soft magnetic underlayer;
a first underlayer made of Ru or an Ru alloy including Ru as a main component, which first underlayer is formed on the seed layer; and
a recording layer that is formed on the first underlayer; wherein
the first underlayer includes a polycrystalline film that is formed by a plurality of first crystal grains that are bonded to each other via a crystal boundary portion;
the recording layer is formed by successively laminating first through n^{th} magnetic layers in consecutive order from the seed layer side (n corresponding to an integer greater than or equal to 3);
the first through n^{th} magnetic layers include a plurality of magnetic grains having easy magnetization axes in a substantially perpendicular direction with respect to the substrate surface, and nonmagnetic non-soluble phases segregating the magnetic grains of the first through n^{th} magnetic layers, respectively; and
atomic concentrations Y1˜Yn of the respective non-soluble phases of the first through n^{th} magnetic layers are arranged such that Y1>Y2> . . . >Yn.

14. A perpendicular magnetic recording medium, comprising:
a substrate;
a soft magnetic underlayer that is formed on the substrate;
a seed layer made of a non-crystalline material, which seed layer is formed on the soft magnetic underlayer;
a first underlayer made of Ru or an Ru alloy including Ru as a main component, which first underlayer is formed on the seed layer;
a recording layer that is formed on the first underlayer; and
a protective film that is formed on the recording layer; wherein
the first underlayer includes a polycrystalline film that is formed by a plurality of first crystal grains that are bonded to each other via a crystal boundary portion;
the recording layer includes a plurality of magnetic grains having easy magnetization axes in a substantially perpendicular direction with respect to the substrate surface, and a nonmagnetic non-soluble phase segregating the magnetic grains; and
an atomic concentration of the non-soluble phase in the recording layer is arranged to gradually decrease in a direction from an interface with the seed layer towards an interface with the protective layer.

15. A perpendicular magnetic recording medium, comprising:
a substrate;
a soft magnetic underlayer that is formed on the substrate;
a seed layer made of a non-crystalline material, which seed layer is formed on the soft magnetic underlayer;
a first underlayer made of Ru or an Ru alloy including Ru as a main component, which first underlayer is formed on the seed layer; and
a recording layer including a first magnetic layer and a second magnetic layer that is laminated on the first magnetic layer, which recording layer is formed on the first underlayer; wherein
the first underlayer includes a polycrystalline film that is formed by a plurality of first crystal grains that are bonded to each other via a crystal boundary portion;
the first magnetic layer includes a plurality of first magnetic grains having easy magnetization axes in a substantially perpendicular direction with respect to the substrate surface, and a nonmagnetic non-soluble phase segregating the first magnetic grains from each other, which first magnetic layer is arranged to have a first saturation flux density;
the second magnetic layer is made of a metallic hard magnetic material and includes a plurality of second magnetic grains having easy magnetization axes in a substantially perpendicular direction with respect to the substrate surface, which second magnetic layer is arranged to have a second saturation flux density;
the second saturation flux density of the second magnetic layer is arranged to be higher than the first saturation flux density of the first magnetic layer; and
the second magnetic grains of the second magnetic layer are arranged on surfaces of the first magnetic grains of the first magnetic layer.

16. The perpendicular magnetic recording medium as claimed in claim 15, wherein
the second magnetic grains of the second magnetic layer are arranged on the surfaces of the first magnetic grains of the first magnetic layer on a one-to-one basis.

17. The perpendicular magnetic recording medium as claimed in claim 15, wherein
the second magnetic layer includes at least one gap formed between adjacent magnetic grains of the second magnetic grains.

18. The perpendicular magnetic recording medium as claimed in claim 15, wherein
the first magnetic grains of the first magnetic layer are made of a hard magnetic material having a hcp structure and including Co as a main component; and
the second magnetic layer is made of a metallic hard magnetic material having a hcp structure and including Co as a main component.

19. A perpendicular magnetic recording medium, comprising:
a substrate;
a soft magnetic underlayer that is formed on the substrate;
a seed layer made of a non-crystalline material, which seed layer is formed on the soft magnetic underlayer;
a first underlayer made of Ru or an Ru alloy including Ru as a main component, which first underlayer is formed on the seed layer; and
a recording layer that is formed on the first underlayer; wherein
the first underlayer includes a polycrystalline film that is formed by a plurality of first crystal grains that are bonded to each other via a crystal boundary portion;
the recording layer is formed by successively laminating first through n^{th} magnetic layers and a metallic magnetic layer in consecutive order from the seed layer side (n corresponding to an integer greater than or equal to 3)
the first through n^{th} magnetic layers include a plurality of magnetic grains having easy magnetization axes in a substantially perpendicular direction with respect to the substrate surface, and nonmagnetic non-soluble phases segregating the magnetic grains of the first through n^{th} magnetic layers, respectively;
atomic concentrations Y1˜Yn of the respective non-soluble phases of the first through n^{th} magnetic layers are arranged such that Y1>Y2> . . . >Yn;
a saturation flux density of the metallic magnetic layer is arranged to be higher than saturation flux densities of the first through n^{th} magnetic layers; and
the metallic magnetic layer includes a plurality of metallic magnetic grains that are arranged on surfaces of the magnetic grains of the n^{th} magnetic layer.

20. A perpendicular magnetic recording medium, comprising:
a substrate;
a soft magnetic underlayer that is formed on the substrate;
a seed layer made of a non-crystalline material, which seed layer is formed on the soft magnetic underlayer;
a first underlayer made of Ru or an Ru alloy including Ru as a main component, which first underlayer is formed on the seed layer;
a recording layer that is formed on the first underlayer; and
a protective film that is formed on the recording layer; wherein
the first underlayer includes a polycrystalline film that is formed by a plurality of first crystal grains that are bonded to each other via a crystal boundary portion;
the recording layer includes a composition modulated layer and a metallic magnetic layer, the composition modulated layer including a plurality of magnetic grains having easy magnetization axes in a substantially perpendicular direction with respect to the substrate surface and a nonmagnetic non-soluble phase segregating the magnetic grains;
an atomic concentration of the non-soluble phase in the composition modulated layer is arranged to gradually decrease in a direction from an interface with the seed layer towards an interface with the metallic magnetic layer;
a saturation flux density of the metallic magnetic layer is arranged to be higher than a saturation flux density of the composition modulated layer; and
the metallic magnetic layer includes a plurality of metallic magnetic grains that are arranged on surfaces of the magnetic grains of the composition modulated layer at the interface with the metallic magnetic layer.

21. The perpendicular magnetic recording medium as claimed in claim 20, further comprising:
a second underlayer made of Ru or an Ru alloy including Ru as a main component, which second underlayer is provided between the first underlayer and the recording layer; wherein
the second underlayer includes a plurality of second crystal grains that are grown in a perpendicular direction with respect to the substrate surface, and a void portion segregating the second crystal grains.

22. A magnetic storage device, comprising:
a recording/reproducing unit including a magnetic head; and
a perpendicular magnetic recording medium including
a substrate;
a soft magnetic underlayer that is formed on the substrate;
a seed layer made of a non-crystalline material, which seed layer is formed on the soft magnetic underlayer;
a first underlayer made of Ru or an Ru alloy including Ru as a main component, which first underlayer is formed on the seed layer; and
a recording layer including a first magnetic layer and a second magnetic layer that is laminated on the first magnetic layer, which recording layer is formed on the first underlayer; wherein
the first underlayer includes a polycrystalline film that is formed by a plurality of first crystal grains that are bonded to each other via a crystal boundary portion;
the first magnetic layer includes a plurality of first magnetic grains having easy magnetization axes in a substantially perpendicular direction with respect to the substrate surface, and a first nonmagnetic non-soluble phase segregating the first magnetic grains from each other, which first non-soluble phase is provided at a first atomic concentration;
the second magnetic layer includes a plurality of second magnetic grains having easy magnetization axes in a substantially perpendicular direction with respect to the substrate surface, and a second nonmagnetic non-soluble phase segregating the second magnetic grains from each other, which second non-soluble phase is provided at a second atomic concentration; and
the first atomic concentration of the first non-soluble phase in the first magnetic layer is arranged to be higher than the second atomic concentration of the second non-soluble phase in the second magnetic phase.

23. A magnetic storage device, comprising:
a recording/reproducing unit including a magnetic head; and
a perpendicular magnetic recording medium including
a substrate;
a soft magnetic underlayer that is formed on the substrate;
a seed layer made of a non-crystalline material, which seed layer is formed on the soft magnetic underlayer;
a first underlayer made of Ru or an Ru alloy including Ru as a main component, which first underlayer is formed on the seed layer; and
a recording layer that is formed on the first underlayer; wherein
the first underlayer includes a polycrystalline film that is formed by a plurality of first crystal grains that are bonded to each other via a crystal boundary portion;
the recording layer is formed by successively laminating first through n^{th} magnetic layers in consecutive order from the seed layer side (n corresponding to an integer greater than or equal to 3);
the first through n^{th} magnetic layers include a plurality of magnetic grains having easy magnetization axes in a substantially perpendicular direction with respect to the substrate surface, and nonmagnetic non-soluble phases segregating the magnetic grains of the first through n^{th} magnetic layers, respectively; and
atomic concentrations Y1˜Yn of the respective non-soluble phases of the first through n^{th} magnetic layers are arranged such that Y1>Y2> . . . >Yn.

24. A magnetic storage device, comprising:
a recording/reproducing unit including a magnetic head; and
a perpendicular magnetic recording medium including
a substrate;
a soft magnetic underlayer that is formed on the substrate;
a seed layer made of a non-crystalline material, which seed layer is formed on the soft magnetic underlayer;
a first underlayer made of Ru or an Ru alloy including Ru as a main component, which first underlayer is formed on the seed layer;
a recording layer that is formed on the first underlayer; and
a protective film that is formed on the recording layer; wherein
the first underlayer includes a polycrystalline film that is formed by a plurality of first crystal grains that are bonded to each other via a crystal boundary portion;
the recording layer includes a plurality of magnetic grains having easy magnetization axes in a substantially perpendicular direction with respect to the substrate surface, and a nonmagnetic non-soluble phase segregating the magnetic grains; and
an atomic concentration of the non-soluble phase in the recording layer is arranged to gradually decrease in a direction from an interface with the seed layer towards an interface with the protective layer.

25. A magnetic storage device, comprising:
a recording/reproducing unit including a magnetic head; and
a perpendicular magnetic recording medium including
a substrate;
a soft magnetic underlayer that is formed on the substrate;
a seed layer made of a non-crystalline material, which seed layer is formed on the soft magnetic underlayer;
a first underlayer made of Ru or an Ru alloy including Ru as a main component, which first underlayer is formed on the seed layer; and
a recording layer including a first magnetic layer and a second magnetic layer that is laminated on the first magnetic layer, which recording layer is formed on the first underlayer; wherein
the first underlayer includes a polycrystalline film that is formed by a plurality of first crystal grains that are bonded to each other via a crystal boundary portion;
the first magnetic layer includes a plurality of first magnetic grains having easy magnetization axes in a substantially perpendicular direction with respect to the substrate surface, and a nonmagnetic non-soluble phase segregating the first magnetic grains from each other, which first magnetic layer is arranged to have a first saturation flux density;
the second magnetic layer is made of a metallic hard magnetic material and includes a plurality of second magnetic grains having easy magnetization axes in a substantially perpendicular direction with respect to the substrate surface, which second magnetic layer is arranged to have a second saturation flux density;
the second saturation flux density of the second magnetic layer is arranged to be higher than the first saturation flux density of the first magnetic layer; and
the second magnetic grains of the second magnetic layer are arranged on surfaces of the first magnetic grains of the first magnetic layer.

26. A magnetic storage device, comprising:
a recording/reproducing unit including a magnetic head; and
a perpendicular magnetic recording medium including
a substrate;
a soft magnetic underlayer that is formed on the substrate;
a seed layer made of a non-crystalline material, which seed layer is formed on the soft magnetic underlayer;
a first underlayer made of Ru or an Ru alloy including Ru as a main component, which first underlayer is formed on the seed layer; and
a recording layer that is formed on the first underlayer; wherein
the first underlayer includes a polycrystalline film that is formed by a plurality of first crystal grains that are bonded to each other via a crystal boundary portion;
the recording layer is formed by successively laminating first through n^{th} magnetic layers and a metallic magnetic layer in consecutive order from the seed layer side (n corresponding to an integer greater than or equal to 3);
the first through n^{th} magnetic layers include a plurality of magnetic grains having easy magnetization axes in a substantially perpendicular direction with respect to the substrate surface, and nonmagnetic non-soluble phases segregating the magnetic grains of the first through n^{th} magnetic layers, respectively;
atomic concentrations Y1˜Yn of the respective non-soluble phases of the first through n^{th} magnetic layers are arranged such that Y1>Y2> . . . >Yn;
a saturation flux density of the metallic magnetic layer is arranged to be higher than saturation flux densities of the first through n^{th} magnetic layers; and
the metallic magnetic layer includes a plurality of metallic magnetic grains that are arranged on surfaces of the magnetic grains of the n^{th} magnetic layer.

27. A magnetic storage device, comprising:
a recording/reproducing unit including a magnetic head; and
a perpendicular magnetic recording medium including
a substrate;
a soft magnetic underlayer that is formed on the substrate;
a seed layer made of a non-crystalline material, which seed layer is formed on the soft magnetic underlayer;
a first underlayer made of Ru or an Ru alloy including Ru as a main component, which first underlayer is formed on the seed layer;
a recording layer that is formed on the first underlayer; and
a protective film that is formed on the recording layer; wherein
the first underlayer includes a polycrystalline film that is formed by a plurality of first crystal grains that are bonded to each other via a crystal boundary portion;
the recording layer includes a composition modulated layer and a metallic magnetic layer, the composition modulated layer including a plurality of magnetic grains having easy magnetization axes in a substantially perpendicular direction with respect to the substrate surface and a nonmagnetic non-soluble phase segregating the magnetic grains;
an atomic concentration of the non-soluble phase in the composition modulated layer is arranged to gradually decrease in a direction from an interface with the seed layer towards an interface with the metallic magnetic layer;
a saturation flux density of the metallic magnetic layer is arranged to be higher than a saturation flux density of the composition modulated layer; and
the metallic magnetic layer includes a plurality of metallic magnetic grains that are arranged on surfaces of the magnetic grains of the composition modulated layer at the interface with the metallic magnetic layer.

28. A method of manufacturing a perpendicular magnetic recording medium that includes a substrate on which a soft magnetic underlayer, a seed layer, a first underlayer, a first magnetic layer, and a second magnetic layer are consecutively formed, which first and second magnetic layers respectively include a plurality of magnetic grains having easy magnetization axes in a direction substantially perpendicular to the substrate surface and nonmagnetic non-soluble phases segregating the magnetic grains, the method comprising the steps of:
forming the seed layer made of a non-crystalline material on the soft magnetic underlayer;
forming the first underlayer made of Ru or an Ru alloy including Ru as main component on the seed layer;
forming the first magnetic layer on the first underlayer through sputtering using a first sputtering target; and
forming the second magnetic layer on the first magnetic layer through sputtering using a second sputtering target; wherein
the first sputtering target and the second sputtering target include a hard magnetic material and a nonmagnetic material that is made of any one of an oxide, a carbide, or a nitride; and
the first sputtering target includes the nonmagnetic material at an atomic concentration that is higher than an atomic concentration of the nonmagnetic material in the second sputtering target.

29. The method for manufacturing a perpendicular magnetic recording medium as claimed in claim 28, wherein
the substrate is not heated while the step of forming the soft magnetic underlayer through the step of forming the step of forming the second magnetic layer are performed.

30. The method for manufacturing a perpendicular magnetic recording medium as claimed in claim 28, further comprising:
a step of forming a second underlayer that is conducted in between the step of forming the first underlayer and the step of forming the first magnetic layer, said step of forming the second underlayer involving conducting a sputtering process at a deposition speed within a range of 0.1˜2 nm/s and at an atmospheric gas pressure within a range of 2.66˜26.6 Pa.

31. A method of manufacturing a perpendicular magnetic recording medium that includes a substrate on which a soft magnetic underlayer, a seed layer, a first underlayer, a first magnetic layer, and a second magnetic layer are consecutively formed, which first and second magnetic layers respectively include a plurality of magnetic grains having easy magnetization axes in a direction substantially perpendicular to the substrate surface and nonmagnetic non-soluble phases segregating the magnetic grains, the method comprising the steps of:
forming the seed layer made of a non-crystalline material on the soft magnetic underlayer;
forming the first underlayer made of Ru or an Ru alloy including Ru as main component on the seed layer;
forming the first magnetic layer on the first underlayer through sputtering using a first sputtering target including a hard magnetic material and a nonmagnetic material that is made of any one of an oxide, a carbide, or a nitride; and
forming the second magnetic layer on the first magnetic layer through sputtering using a second sputtering target that is made of a hard magnetic material.

32. The method for manufacturing a perpendicular magnetic recording medium as claimed in claim 31, wherein
the substrate is not heated while the step of forming the soft magnetic underlayer through the step of forming the step of forming the second magnetic layer are performed.

33. The method for manufacturing a perpendicular magnetic recording medium as claimed in claim 31, further comprising:
a step of forming a second underlayer that is conducted in between the step of forming the first underlayer and the step of forming the first magnetic layer, said step of forming the second underlayer involving conducting a sputtering process at a deposition speed within a range of 0.1˜2 nm/s and at an atmospheric gas pressure within a range of 2.66˜26.6 Pa.
